(19) United States
(12) Patent Application Publication
(10) Pub. No.: US 2024/0321601 A1
(43) Pub. Date: Sep. 26, 2024

(54) CLEANING APPARATUS, SUBSTRATE PROCESSING APPARATUS, AND CLEANING METHOD

(71) Applicant: EBARA CORPORATION, Tokyo (JP)

(72) Inventors: Fumitoshi OIKAWA, Tokyo (JP); Koichi FUKAYA, Tokyo (JP); Hiroki TAKAHASHI, Tokyo (JP); Akira IMAMURA, Tokyo (JP)

(21) Appl. No.: 18/611,156

(22) Filed: Mar. 20, 2024

(30) Foreign Application Priority Data
Mar. 24, 2023 (JP) 2023-048116

(51) Int. Cl. H01L 21/67; B08B 1/34; B08B 3/02; B08B 3/04; H01L 21/02

(52) U.S. Cl. CPC H01L 21/67051; B08B 1/34; B08B 3/022; B08B 3/041; H01L 21/02057; H01L 21/67034

(57) ABSTRACT

A cleaning apparatus includes: a rotation support section that supports and rotates a substrate; a chemical liquid supply section that supplies a chemical liquid other than an organic solvent to a surface of the substrate; an organic solvent supply section that supplies an organic solvent to a surface of the substrate; and cleaning means that cleans a surface of the substrate supported by the rotation support section using a chemical liquid from the chemical liquid supply section, and then cleans a surface of the substrate using an organic solvent from the organic solvent supply section with the substrate being kept supported by the rotation support section.

### CROSS-REFERENCE TO RELATED APPLICATIONS

This application claims the benefit of Japanese Priority Patent Application JP 2023-048116 filed on Mar. 24, 2023, the entire contents of which are incorporated herein by reference.

### FIELD

The present technique relates to a cleaning apparatus, a substrate processing apparatus, and a cleaning method.

### BACKGROUND AND SUMMARY

In recent years, as semiconductor devices have become more highly integrated, circuit wiring has become finer and the distance between wiring has become narrower. In the manufacture of semiconductor devices, many types of materials are repeatedly formed into films on a silicon wafer to form a laminated structure. To form this laminated structure, a technique for planarizing the surface of the wafer is important. As means for planarizing the surface of such a wafer, a polishing apparatus that performs chemical mechanical polishing (CMP) is widely used, which apparatus is also referred to as a chemical mechanical polishing apparatus.

The chemical mechanical polishing (CMP) apparatus generally includes a polishing table to which a polishing pad is attached, a top ring that holds a wafer, and a nozzle that supplies polishing liquid (slurry) onto the polishing pad. While the nozzle supplies polishing liquid onto the polishing pad, the top ring presses the wafer against the polishing pad, and the top ring and polishing table are moved relative to each other, to polish the wafer and planarize its surface.

In addition to such a CMP apparatus, the substrate processing apparatus also has the function of cleaning and further drying the polished wafer. In such a substrate processing apparatus, conventional cleaning after polishing mainly involves removing particles and metal contamination using pure water or chemical liquid (other than an organic solvent).

However, as the number of new materials used for film formation in semiconductor manufacturing increases and the required level of cleanliness after polishing processing increases, conventional cleaning using pure water or chemical liquid has been found insufficient. In particular, there is an increasing demand for dissolving and removing certain types of organic residues (for example, additives contained in slurry to improve the dispersibility of slurry or to prevent corrosion of metals).

It is conceivable for this to add a cleaning process specialized for dissolving and removing organic residues using a stand-alone cleaning apparatus after polishing, cleaning, and drying in the substrate processing apparatus. However, there is a problem of increase in the apparatus cost, number of processes, and TAT (turnaround time) of the stand-alone cleaning apparatus. Japanese Patent Laid-Open No. 2006-203027 proposes sequentially performing: cleaning using a chemical liquid in an abrasive metal contamination cleaning section 12; drying; and then cleaning in an organic solvent cleaning section 13. However, there is a problem of increase in size of the apparatus and a large impact on throughput.

It is desirable to provide a cleaning apparatus, a substrate processing apparatus, and a cleaning method capable of dissolving and removing organic residues without increasing a size of the entire apparatus.

A cleaning apparatus according to an embodiment includes:
a rotation support section that supports and rotates a substrate;
a chemical liquid supply section that supplies a chemical liquid other than an organic solvent to a surface of the substrate;
an organic solvent supply section that supplies an organic solvent to a surface of the substrate; and
cleaning means that cleans a surface of the substrate supported by the rotation support section using a chemical liquid from the chemical liquid supply section, and then cleans a surface of the substrate using an organic solvent from the organic solvent supply section with the substrate being kept supported by the rotation support section.

A cleaning apparatus according to another embodiment includes:
a rotation support section that supports and rotates a substrate;
an organic solvent supply section that supplies an organic solvent to a surface of the substrate;
a non-contact cleaning nozzle that sprays fluid onto a surface of the substrate supported by the rotation support section to clean the surface when an organic solvent is supplied from the organic solvent supply section; and
a drying nozzle that sprays organic solvent vapor onto a surface of the substrate to dry the surface with the substrate being kept supported by the rotation support section.

A cleaning method according to an embodiment includes:
a step of supporting and rotating a substrate with a rotation support section;
a step of cleaning a surface of the substrate supported by the rotation support section using a chemical liquid; and
a step of cleaning a surface of the substrate using an organic solvent with the substrate being kept supported by the rotation support section.

A cleaning method according to another embodiment includes:
a step of supporting and rotating a substrate with a rotation support section;
a step of cleaning a surface of the substrate supported by the rotation support section using an organic solvent; and
a step of spraying organic solvent vapor onto a surface of the substrate to dry the surface with the substrate being kept supported by the rotation support section.

### BRIEF DESCRIPTION OF DRAWINGS

FIG. 1 is a plan view showing an overall configuration of a substrate processing apparatus according to an embodiment;

FIG. 2 is a plan view showing a schematic configuration of an example of a cleaning apparatus in a first cleaning module;

FIG. 3 is a diagram showing a cross section of the cleaning apparatus shown in FIG. 2 taken along a dashed-dotted line indicated by a symbol A-A;

FIG. 4A is a plan view for describing operation when cleaning is performed using a chemical in the cleaning apparatus shown in FIG. 2, and FIG. 4B is a side view of the same;

FIG. 5A is a plan view for describing operation when cleaning is performed using an organic solvent in the cleaning apparatus shown in FIG. 2, and FIG. 5B is a side view of the same;

FIG. 6 is a plan view showing a schematic configuration of another example of a cleaning apparatus in the first cleaning module;

FIG. 7 is a plan view showing a schematic configuration of an example of a cleaning apparatus in a second cleaning module;

FIG. 8 is a plan view showing a schematic configuration of an example of a cleaning apparatus in a third cleaning module;

FIG. 9A is a plan view for describing an example of a configuration of a pen cleaning member in the cleaning apparatus shown in FIG. 8, and FIG. 9B and FIG. 9C are internal side views of the same;

FIG. 10 is an internal side view for describing an example of a configuration of a two-fluid jet nozzle in the cleaning apparatus shown in FIG. 8;

FIG. 11 is a diagram for describing an example of piping of the cleaning apparatus shown in FIG. 8;

FIG. 12 is a plan view showing a schematic configuration of an example of a cleaning apparatus in a fourth cleaning module (drying module);

FIG. 13 is a diagram for describing an example of piping of the cleaning apparatus shown in FIG. 12;

FIG. 14 is a diagram for describing a modification of piping of the cleaning apparatus shown in FIG. 12;

FIG. 15 is a table showing an example of a cleaning sequence for a substrate having tungsten or silicon oxide on a surface (device forming surface);

FIG. 16 is a table showing another example of a cleaning sequence for a substrate having tungsten or silicon oxide on a surface (device forming surface);

FIG. 17 is a table showing an example of a cleaning sequence for a substrate having copper on a surface (device forming surface); and

FIG. 18 is a table showing another example of a cleaning sequence for a substrate having copper on a surface (device forming surface).

### DETAILED DESCRIPTION OF NON-LIMITING EXAMPLE EMBODIMENTS

A cleaning apparatus, according to a first aspect of an embodiment, includes:
a rotation support section that supports and rotates a substrate;
a chemical liquid supply section that supplies a chemical liquid other than an organic solvent to a surface of the substrate;
an organic solvent supply section that supplies an organic solvent to a surface of the substrate; and
cleaning means that cleans a surface of the substrate supported by the rotation support section using a chemical liquid from the chemical liquid supply section, and then cleans a surface of the substrate using an organic solvent from the organic solvent supply section with the substrate being kept supported by the rotation support section.

According to this aspect, cleaning the wafer sequentially using both a chemical liquid other than an organic solvent and an organic solvent in one unit makes it possible to reliably dissolve and remove the organic residues without increasing the size of the entire apparatus while maintaining the cleaning effect of the conventional chemical liquid. Furthermore, there is no need to add a stand-alone cleaning apparatus specialized for dissolving and removing organic residues, allowing the apparatus cost to be reduced. Furthermore, since organic residues are removed in one unit, there is no increase in the number of processes and TAT. Furthermore, since the throughput of a substrate processing apparatus is typically rate-limited by polishing, adding a cleaning sequence using an organic solvent to the cleaning processing does not affect the throughput of the apparatus unless the total sequence is longer than the polishing in terms of time.

A cleaning apparatus according to a second aspect of the embodiment is the cleaning apparatus according to the first aspect, in which
the cleaning means includes:
   a first contact cleaning member that comes into contact with a surface of the substrate to clean the surface when a chemical liquid is supplied from the chemical liquid supply section; and

a second contact cleaning member different from the first contact cleaning member, the second contact cleaning member coming into contact with a surface of the substrate to clean the surface when an organic solvent is supplied from the organic solvent supply section.

A cleaning apparatus according to a third aspect of the embodiment is the cleaning apparatus according to the second aspect, in which
each of the first contact cleaning member and the second contact cleaning member is a pen cleaning member or a buff cleaning member that comes into contact with a surface of the substrate while rotating around a central axis perpendicular to the surface of the substrate to clean the surface.

A cleaning apparatus according to a fourth aspect of the embodiment is the cleaning apparatus according to the third aspect, in which
the first contact cleaning member and the second contact cleaning member are coaxially placed and supported on an identical swing arm in a plan view.

A cleaning apparatus according to a fifth aspect of the embodiment is the cleaning apparatus according to the second aspect, in which
each of the first contact cleaning member and the second contact cleaning member is a roll cleaning member that comes into contact with a surface of the substrate to clean the surface while rotating around a central axis parallel to the surface of the substrate.

A cleaning apparatus according to a sixth aspect of the embodiment is the cleaning apparatus according to any one of the second to fifth aspects, in which
a material of the second contact cleaning member is polytetrafluoroethylene (PTFE).

A cleaning apparatus according to a seventh aspect of the embodiment is the cleaning apparatus according to the first aspect, in which
the cleaning means includes a non-contact cleaning nozzle that sprays fluid onto a surface of the substrate to clean the surface when a chemical liquid is supplied from the chemical liquid supply section and when an organic solvent is supplied from the organic solvent supply section.

A cleaning apparatus according to an eighth aspect of the embodiment is the cleaning apparatus according to the seventh aspect, in which
the non-contact cleaning nozzle is a two-fluid jet nozzle that sprays a jet stream containing a mixture of liquid and carrier gas, or a megasonic nozzle that sprays a liquid excited by an ultrasonic vibrator.

A cleaning apparatus according to a ninth aspect of the embodiment is the cleaning apparatus according to the seventh or eighth aspect, in which
the chemical liquid supply section and/or the organic solvent supply section are provided in the non-contact cleaning nozzle.

A cleaning apparatus according to a tenth aspect of the embodiment is the cleaning apparatus according to the first aspect, in which
the cleaning means includes:
   a contact cleaning member that comes into contact with a surface of the substrate to clean the surface when a chemical liquid is supplied from the chemical liquid supply section; and
   a non-contact cleaning nozzle that sprays fluid onto a surface of the substrate to clean the surface when an organic solvent is supplied from the organic solvent supply section.

A cleaning apparatus according to an eleventh aspect of the embodiment is the cleaning apparatus according to the tenth aspect, in which
the non-contact cleaning nozzle sprays fluid onto a surface of the substrate to clean the surface also when a chemical liquid is supplied from the chemical liquid supply section.

A cleaning apparatus according to a twelfth aspect of the embodiment is the cleaning apparatus according to the first aspect, in which
the cleaning means includes:
   a non-contact cleaning nozzle that sprays fluid onto a surface of the substrate to clean the surface when a chemical liquid is supplied from the chemical liquid supply section; and
   a contact cleaning member that comes into contact with a surface of the substrate to clean the surface when an organic solvent is supplied from the organic solvent supply section.

A cleaning apparatus according to a thirteenth aspect of the embodiment is the cleaning apparatus according to the twelfth aspect, in which
the non-contact cleaning nozzle sprays fluid onto a surface of the substrate to clean the surface also when an organic solvent is supplied from the organic solvent supply section.

A cleaning apparatus according to a fourteenth aspect of the embodiment is the cleaning apparatus according to any one of the tenth to thirteenth aspects, in which
a material of the contact cleaning member is polytetrafluoroethylene (PTFE).

A cleaning apparatus according to a fifteenth aspect of the embodiment is the cleaning apparatus according to any one of the tenth to thirteenth aspects, in which
the contact cleaning member is a pen cleaning member or a buff cleaning member that comes into contact with a surface of the substrate to clean the surface while rotating around a central axis perpendicular to the surface of the substrate.

A cleaning apparatus according to a sixteenth aspect of the embodiment is the cleaning apparatus according to any one of the tenth to thirteenth aspects, in which
the contact cleaning member is a roll cleaning member that comes into contact with a surface of the substrate to clean the surface while rotating around a central axis parallel to the surface of the substrate.

A cleaning apparatus according to a seventeenth aspect of the embodiment is the cleaning apparatus according to the tenth to thirteenth aspects, in which
the non-contact cleaning nozzle is a two-fluid jet nozzle that sprays a jet stream containing a mixture of liquid and carrier gas, or a megasonic nozzle that sprays a liquid excited by an ultrasonic vibrator.

A cleaning apparatus, according to an eighteenth aspect of the embodiment, that further includes:
a rotation support section that supports and rotates a substrate;
an organic solvent supply section that supplies an organic solvent to a surface of the substrate;
a non-contact cleaning nozzle that sprays fluid onto a surface of the substrate supported by the rotation support section to clean the surface when an organic solvent is supplied from the organic solvent supply section; and
a drying nozzle that sprays organic solvent vapor onto a surface of the substrate to dry the surface with the substrate being kept supported by the rotation support section.

According to this aspect, sequentially performing both cleaning and drying using an organic solvent in one unit makes it possible to reliably dissolve and remove the organic residues without increasing the size of the entire apparatus while maintaining the drying effect of the conventional organic solvent. Furthermore, there is no need to add a stand-alone cleaning apparatus specialized for dissolving and removing organic residues, allowing the apparatus cost to be reduced. Furthermore, since organic residues are removed in one unit, there is no increase in the number of processes and TAT. Furthermore, since the throughput of a substrate processing apparatus is typically rate-limited by polishing, adding a cleaning sequence using an organic solvent to the drying processing does not affect the throughput of the apparatus unless the total sequence is longer than the polishing in terms of time.

A cleaning apparatus according to a nineteenth aspect of the embodiment is the cleaning apparatus according to the eighteenth aspect, in which
the non-contact cleaning nozzle is a two-fluid jet nozzle that sprays a jet stream containing a mixture of liquid and carrier gas, or a megasonic nozzle that sprays a liquid excited by an ultrasonic vibrator.

A cleaning apparatus according to a twentieth aspect of the embodiment is the cleaning apparatus according to the eighteenth or nineteenth aspect, in which
the organic solvent supply section is provided in the non-contact cleaning nozzle.

A cleaning apparatus according to a twenty-first aspect of the embodiment is the cleaning apparatus, according to the first or eighteenth aspect, that further includes
an organic solvent heating section that is disposed on an upstream side of the organic solvent supply section, and dilutes and heats, with warm water, an organic solvent to be supplied to the organic solvent supply section.

A cleaning apparatus according to a twenty-second aspect of the embodiment is the cleaning apparatus, according to the first or eighteenth aspect, that further includes
a first warm water supply nozzle that supplies warm water to a surface of the substrate to dilute and heat an organic solvent from the organic solvent supply section on the surface of the substrate when the organic solvent is supplied from the organic solvent supply section.

A cleaning apparatus according to a twenty-third aspect of the embodiment is the cleaning apparatus, according to any one of the first, eighteenth, and twenty-second aspects, that further includes
a second warm water supply nozzle that supplies warm water to a back surface of the substrate to heat the substrate when an organic solvent is supplied from the organic solvent supply section, and thereby heats the organic solvent from the organic solvent supply section on a front surface of the substrate with heat of the substrate.

A substrate processing apparatus, according to a twenty-fourth aspect of the embodiment, includes:
a polishing section that polishes a substrate; and
a cleaning section that cleans a polished substrate,
in which the cleaning section includes a cleaning apparatus according to the first or eighteenth aspect.

A cleaning method, according to a twenty-fifth aspect of the embodiment, includes:
a step of supporting and rotating a substrate with a rotation support section;
a step of cleaning a surface of the substrate supported by the rotation support section using a chemical liquid; and
a step of cleaning a surface of the substrate using an organic solvent with the substrate being kept supported by the rotation support section.

A cleaning method, according to a twenty-sixth aspect of the embodiment, includes:
a step of supporting and rotating a substrate with a rotation support section;
a step of cleaning a surface of the substrate supported by the rotation support section using an organic solvent; and
a step of spraying organic solvent vapor onto a surface of the substrate to dry the surface with the substrate being kept supported by the rotation support section.

Hereinafter, specific examples of embodiments will be described in detail with reference to the accompanying drawings. Note that, in the following description and the drawings used in the following description, the same reference numerals and characters are used for parts that can be configured in the same way, and duplicate description thereof is omitted.

### <Configuration of Substrate Processing Apparatus>

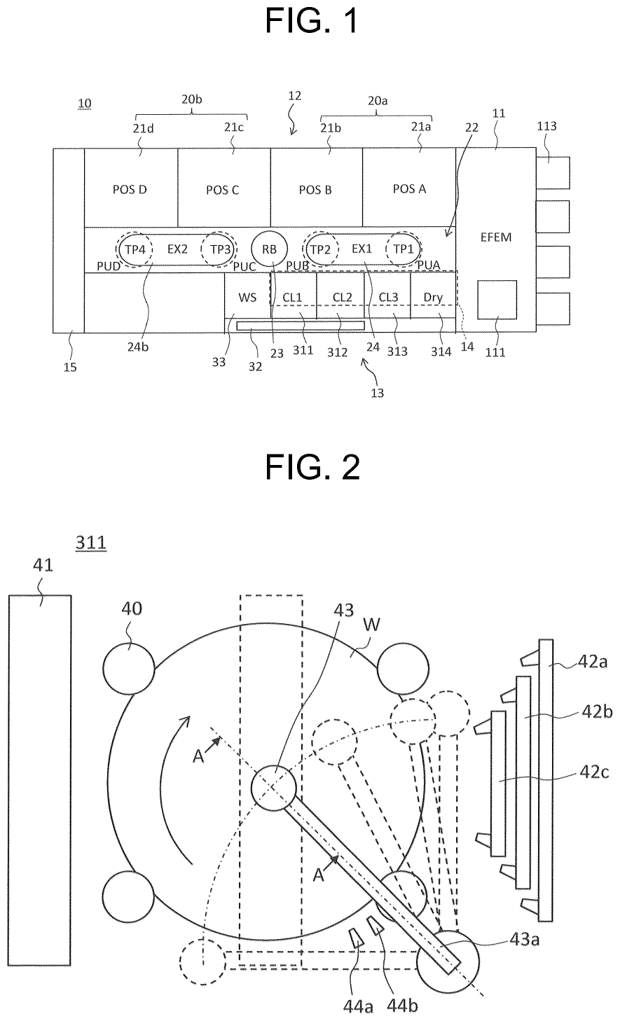

FIG. 1 is a plan view showing an overall configuration of a substrate processing apparatus according to an embodiment. As shown in FIGS. 1 and 2, the substrate processing apparatus 10 includes a housing that is substantially rectangular in a plan view. The inside of the housing is divided into a loading/unloading section 11, a polishing section 12, a cleaning section 13, and a transfer section 14, by partition walls. The loading/unloading section 11, the polishing section 12, the cleaning section 13, and the transfer section 14 are each independently assembled and independently evacuated. Furthermore, the substrate processing apparatus 10 is provided with a control section 15 (also referred to as a control panel) that controls operation of the loading/unloading section 11, the polishing section 12, the cleaning section 13, and the transfer section 14.

Among these, the loading/unloading section 11 includes a plurality of (four in the illustrated example) front loading sections 113 on which wafer cassettes for stocking a large number of wafers (substrates) W are placed, and a transfer robot 111 that is movable in the arrangement direction of the front loading section 113 (in the illustrated example, the width direction of the substrate processing apparatus 10). As a specific configuration of the loading/unloading section 11, for example, the configuration described in Japanese Patent No. 6727044 can be employed. The transfer robot 111 is configured to take out an unpolished wafer W from a wafer cassette in the front loading section 113 and transfers the wafer W to the transfer section 14 (described later). The transfer robot 111 is also configured to take out a cleaned and dried wafer W from a cleaning section 13, which will be described later, and return the wafer W to the wafer cassette.

The transfer section 14 is an area for transferring the unpolished wafer W from the loading/unloading section 11 to the polishing section 12, and is provided so as to extend in the longitudinal direction of the substrate processing apparatus 10. The transfer section 14 includes a slide stage (not shown) that holds the wafer W, and a stage moving mechanism (not shown) that linearly moves the slide stage in the longitudinal direction. As a specific configuration of the transfer section 14, for example, the configuration described in Japanese Patent No. 6727044 can be employed. The unpolished wafer W is transferred from the transfer robot 111 of the loading/unloading section 11 to the transfer section 14. The wafer W is then placed on a slide stage and moved to a position where the wafer W can be accessed by the transfer robot 23 of the polishing section 12, which will be described later.

The polishing section 12 is an area where wafers W are polished. The polishing section 12 includes: a first polishing unit 20a having a first polishing apparatus 21a and a second polishing apparatus 21b; a second polishing unit 20b having a third polishing apparatus 21c and a fourth polishing apparatus 21d; and a polishing section transfer mechanism 22 disposed so as to be adjacent to the transfer section 14, the first polishing unit 20a, and the second polishing unit 20b, respectively. As a specific configuration of the polishing section 12, for example, the configuration described in Japanese Patent No. 6727044 can be employed. The first polishing apparatus 21a, the second polishing apparatus 21b, the third polishing apparatus 21c, and the fourth polishing apparatus 21d are arranged in the longitudinal direction of the substrate processing apparatus 10. The polishing section transfer mechanism 22 is disposed between: the cleaning section 13; and the first polishing unit 20a and the second polishing unit 20b in the width direction of the substrate processing apparatus 10.

The polishing section transfer mechanism 22 includes: a first transfer unit 24a that transfers the wafer W to the first polishing unit 20a; a second transfer unit 24b that transfers the wafer W to the second polishing unit 20b; and a transfer robot 23 that is disposed between the first transfer unit 24a and the second transfer unit 24b, and transfers wafers between the transfer section 14, and the first transfer unit 24a and the second transfer unit 24b. In the illustrated example, the transfer robot 23 is disposed approximately at the center of the housing of the substrate processing apparatus 10.

The unpolished wafers W continuously transferred from the transfer section 14 to the polishing section 12 are allocated by the transfer robot 23 to the first transfer unit 24a and the second transfer unit 24b. The wafers W allocated to the first transfer unit 24a are then carried into the first polishing unit 20a and polished by the polishing apparatuses 21a and/or 21b of the first polishing unit 20a. The wafers W allocated to the second transfer unit 24b are carried into the second polishing unit 20b, and are polished by the polishing apparatuses 21c and/or 21d of the second polishing unit 20b.

The wafer W polished by the polishing apparatuses 21a and 21b of the first polishing unit 20a is transferred from the first polishing unit 20a to the first transfer unit 24a. The wafer W is then taken out from the first transfer unit 24a by the transfer robot 23 and transferred to a wafer station 33 of the cleaning section 13, which will be described later. Likewise, the wafer W polished by the polishing apparatuses 21c and 21d of the second polishing unit 20b is transferred from the second polishing unit 20b to the second transfer unit 24b. The wafer W is then taken out from the second transfer unit 24b by the transfer robot 23 and transferred to a wafer station 33 of the cleaning section 13, which will be described later.

The cleaning section 13 is an area for cleaning polished wafers. In the example shown in FIG. 1, the cleaning section 13 and the transfer section 14 are arranged so as to overlap in the up-down direction, providing an advantage of a small footprint.

As shown in FIG. 1, the cleaning section 13 includes: a plurality of (four in the illustrated example) cleaning modules 311, 312, 313, and 314; a wafer station 33; and a cleaning section transfer mechanism 32 that transfers the wafer W between each of the cleaning modules 311 to 314 and the wafer station 33. In the illustrated example, four cleaning modules 311 to 314 (hereinafter sometimes referred to as the first to fourth cleaning modules) are disposed in series in this order from the wafer station 33. As a specific configuration of the wafer station 33 and the cleaning section transfer mechanism 32, for example, the configuration described in Japanese Patent No. 6727044 can be employed. The configuration of the cleaning apparatus included in each of the cleaning modules 311 to 314 will be described later.

The polished wafer W transferred from the transfer robot 23 to the wafer station 33 is transferred from the wafer station 33 to the first cleaning module 311 by the cleaning section transfer mechanism 32, and the wafer W is then cleaned in the cleaning apparatus of the first cleaning module 311.

After the cleaning processing in the first cleaning module 311 is completed, the wafer W is transferred from the first cleaning module 311 to the second cleaning module 312 by the cleaning section transfer mechanism 32, and the wafer W is then cleaned in the cleaning apparatus of the second cleaning module 312.

After the cleaning processing in the second cleaning module 312 is completed, the wafer W is transferred from the second cleaning module 312 to the third cleaning module 313 by the cleaning section transfer mechanism 32, and the wafer W is then cleaned in the cleaning apparatus of the third cleaning module 313.

After the cleaning processing in the third cleaning module 313 is completed, the wafer W is transferred from the third cleaning module 313 to the fourth cleaning module 314 by the cleaning section transfer mechanism 32, and the wafer W is then cleaned and dried in the cleaning apparatus of the fourth cleaning module 314. The cleaned and dried wafer W is taken out by the transfer robot 111 of the loading/unloading section 11 and returned to the wafer cassette 113.

### <Configuration of Cleaning Apparatus>

Next, the cleaning apparatuses included in each of the cleaning modules 311 to 314 will be described. Note that, hereinafter, the cleaning apparatuses of each of the cleaning modules 311 to 314 may be described by using the same reference numerals 311 to 314 as the cleaning modules.

### (First Cleaning Module)

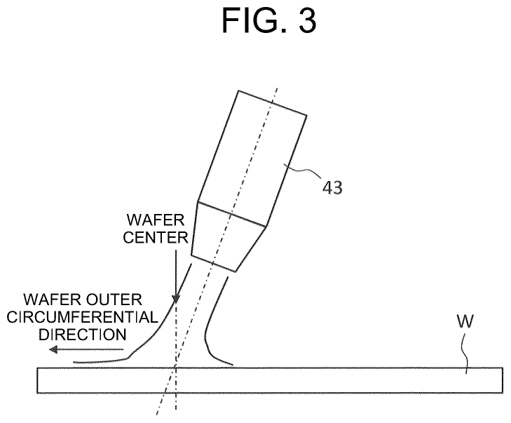

FIG. 2 is a plan view showing a schematic configuration of an example of the cleaning apparatus included in the first cleaning module 311. FIG. 3 is a diagram showing a cross section of the cleaning apparatus shown in FIG. 2 taken along a dashed-dotted line indicated by a symbol A-A.

As shown in FIGS. 2 and 3, the cleaning apparatus 311 includes: a rotation support section 40 that supports and rotates the wafer W; a rinsing liquid supply section 42a that supplies a rinsing liquid such as ultrapure water (DIW) to the surface of the wafer W; chemical liquid supply sections 42b and 44a each of which supplies a chemical liquid other than an organic solvent to the surface of the wafer W in which the chemical liquid is, for example, ammonia-hydrogen peroxide mixture (SC1), hydrochloric acid-hydrogen peroxide mixture (SC2), sulfuric acid-hydrogen peroxide (SPM), sulfuric acid hydrogen, or hydrofluoric acid; organic solvent supply sections 42c and 44b that supply an organic solvent (for example, dimethyl sulfoxide (DMSO)) to the surface of the wafer W; and cleaning means 41 and 43 that clean the surface of the wafer W supported by the rotation support section 40 using a chemical liquid from the chemical liquid supply sections 42b and 44a, and then clean the surface of the wafer W using an organic solvent from the organic solvent supply sections 42c and 44a while the wafer W is kept supported by the rotation support section 40.

Of these, the rotation support section 40 has a plurality of (four in the illustrated example) rotating rollers that come into contact with the outer circumferential portion of the wafer W to support the wafer W. When each rotating roller rotates around the central shaft (counterclockwise in the illustrated example), the rotational force of each rotating roller is transmitted to the outer circumferential portion of the wafer W and the wafer W is rotated around the central shaft (clockwise in the illustrated example).

In the example shown in FIGS. 2 and 3, the cleaning means 41 and 43 include a contact cleaning member 41 that comes into contact with the surface of the wafer W to clean the surface, and a non-contact cleaning nozzle 43 that sprays fluid onto the surface of the wafer W to clean the surface. Furthermore, the chemical liquid supply sections 42b and 44a include a contact cleaning chemical liquid supply section 42b and a non-contact cleaning chemical liquid supply section 44a. The organic solvent supply sections 42c and 44b include a contact cleaning organic solvent supply section 42c and a non-contact cleaning organic solvent supply section 44b.

In the present embodiment, as shown in FIG. 3, the non-contact cleaning member 43 is a megasonic nozzle that sprays liquid (for example, pure water) excited by an ultrasonic vibrator toward the center of the wafer W. As shown in FIG. 2, the megasonic nozzle 43 is disposed at the head end of a swing arm 43a, and swings in a direction parallel to the surface of the wafer W with the base end portion of the swing arm 43a as a rotating shaft. The non-contact cleaning chemical liquid supply section 44a and the non-contact cleaning organic solvent supply section 44b are disposed outside the wafer W (in the illustrated example, on the base end portion side of the swing arm 43a).

Furthermore, in the present embodiment, as shown in FIG. 2, the contact cleaning member 41 is a roll cleaning member that comes into contact with the surface of the wafer W to clean the surface while rotating around a central axis parallel to the surface of the wafer W. The roll cleaning member 41 is moved between a cleaning position over the center of the wafer W and a retracted position outside the wafer W by a moving mechanism (not shown).

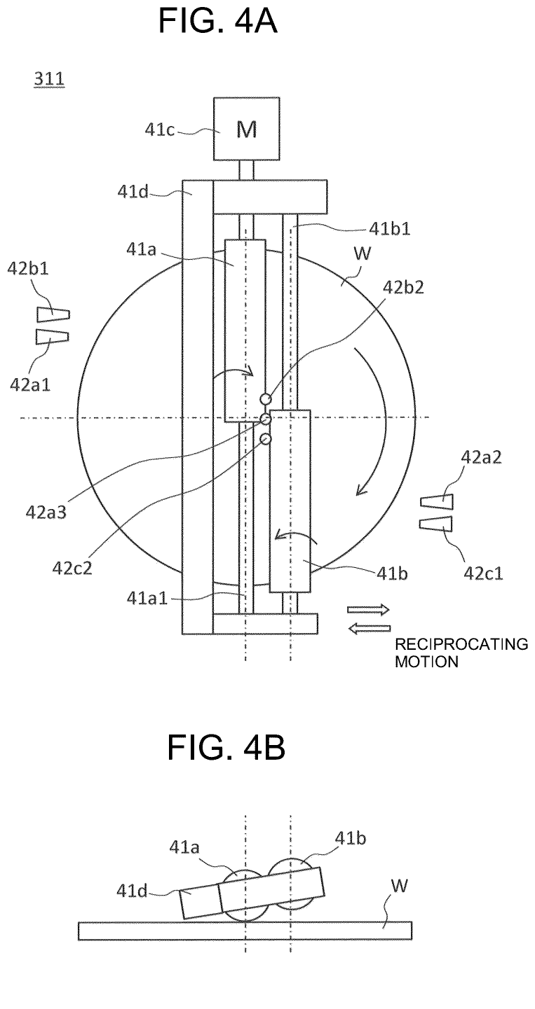

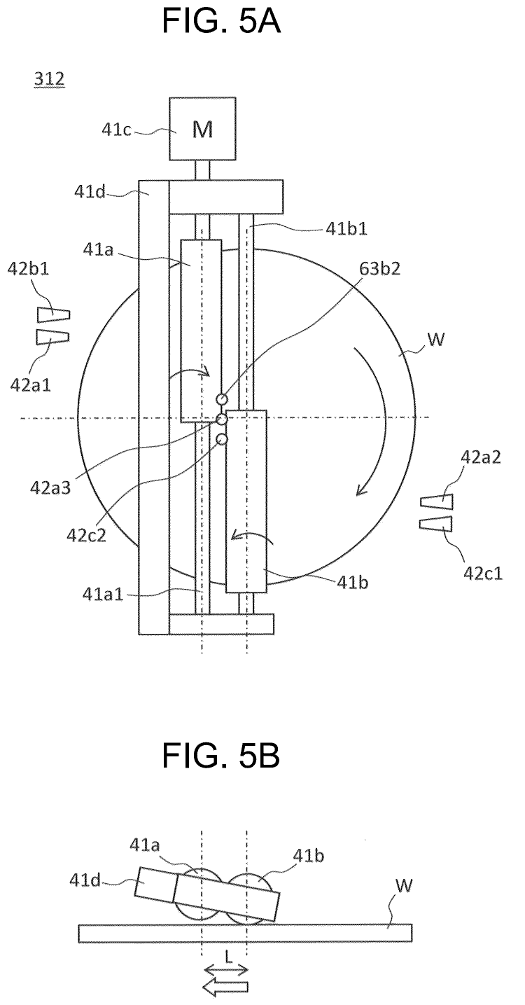

An example of the configuration of the roll cleaning member 41 will be described in detail with reference to FIGS. 4A, 4B, 5A, and 5B. As shown in FIGS. 4A, 4B, 5A and 5B, the roll cleaning member 41 includes: a first roll cleaning member 41a and a second roll cleaning member 41b each having a length approximately equal to the radius of the wafer W; a roll holding section 41d that rotatably holds the rotating shafts 41a1 and 41b1 of the first roll cleaning member 41a and the second roll cleaning member 41b; rotating motor 41c; and a roll pressing section (not shown) that presses the first roll cleaning member 41a and the second roll cleaning member 41b against the surface of the wafer W.

Of these, the first roll cleaning member 41a is, for example, a cylindrical roll sponge made of PVA (polyvinyl alcohol). The second roll cleaning member 41b is, for example, a cylindrical roll sponge made of PTFE (polytetrafluoroethylene). The first roll cleaning member 41a and the second roll cleaning member 41b are oriented such that their central axes are parallel to each other, and are disposed so as to cover radial portions of the surface of the wafer W that are opposite to each other.

The roll holding section 41d has a U-shape in a plan view, and rotatably supports both ends of the rotating shafts 41a1 and 41b1 of the first roll cleaning member 41a and the second roll cleaning member 41b, respectively. Furthermore, the roll holding section 41d is provided with a rotation transmission mechanism, for example, a pulley or a gear (not shown), that transmits the rotational force of the first roll cleaning member 41a to the second roll cleaning member 41b.

The rotating motor 41c is connected to one end of the rotating shaft 41a1 of the first roll cleaning member 41a, and directly transmits rotational force to the rotating shaft 41a1 of the first roll cleaning member 41a to rotate the first roll cleaning member 41a about the central axis. Furthermore, when the first roll cleaning member 41a is rotated, the rotational force of the first roll cleaning member 41a is transmitted to the second roll cleaning member 41b via a rotation transmission mechanism (not shown), and the second roll cleaning member 41b is also rotated about the central axis.

As shown in FIG. 4B, a roll pressing section (not shown) presses with the roll holding section 41d tilted so that the second roll cleaning member 41b is placed at a higher height position than the first roll cleaning member 41a, thereby pressing the first roll cleaning member 41a against the surface of the wafer W with the second roll cleaning member 41b being spaced apart from the surface of the wafer W. In addition, as shown in FIG. 4B, a roll pressing section (not shown) presses with the roll holding section 41d tilted so that the first roll cleaning member 41a is placed at a higher height position than the second roll cleaning member 41b, thereby pressing the second roll cleaning member 41b against the surface of the wafer W with the first roll cleaning member 41a being spaced apart from the surface of the wafer W. This makes it possible to use different roll sponges in chemical liquid cleaning and organic solvent cleaning.

In the illustrated example, the rinsing liquid supply section 42a includes a first rinsing liquid nozzle 42a1 outside the wafer W that supplies a rinsing liquid to an area covered by the first roll cleaning member 41a, a second rinsing liquid nozzle 42a2 outside the wafer W that supplies rinsing liquid to an area covered by the second roll cleaning member 41b; and a third rinsing liquid nozzle 42a3 that is held by the roll holding section 41d and supplies a rinsing liquid between the first roll cleaning member 41a and the second roll cleaning member 41b. Furthermore, the contact cleaning chemical liquid supply section 42b includes a first chemical liquid nozzle 42b1 outside the wafer W that supplies a rinsing liquid to an area covered by the first roll cleaning member 41a, and a second chemical liquid nozzle 42b2 that is held by the roll holding section 41d and supplies a chemical liquid between the first roll cleaning member 41a and the second roll cleaning member 41b. Furthermore, the contact cleaning organic solvent supply section 42c includes a first organic solvent nozzle 42c1 outside the wafer W that supplies a rinsing liquid to an area covered by the second roll cleaning member 41b on the outside of the wafer W, and a second organic solvent nozzle 42c2 that is held by the roll holding section 41d and supplies a chemical liquid between the first roll cleaning member 41a and the second roll cleaning member 41b.

Next, an example of the operation of the cleaning apparatus 311 having the above configuration will be described. First, the surface of the wafer W is cleaned with a chemical liquid. As an example of chemical liquid cleaning, as shown in FIG. 4A, the surface of the wafer W is subjected to contact cleaning using a chemical liquid with the first roll cleaning member 41a by: rotating the wafer W supported by the rotation support section 40, and moving the first roll cleaning member 41a to a position over the radius of the wafer W; supplying the chemical liquid to the surface of the wafer W from the first chemical liquid nozzle 42b1 and the second chemical liquid nozzle 42b2; and pressing the first roll cleaning member 41a against the surface of the wafer W with the surface of the wafer W being wetted with the chemical liquid, while the first roll cleaning member 41a is rotated about the central axis. At this time, as shown in FIG. 4A, the roll holding section 41d is tilted so that the second roll cleaning member 41b is placed at a higher height position than the first roll cleaning member 41a, and the second roll cleaning member 41b is not pressed against the surface of the wafer W but is spaced apart from the surface.

As another example of chemical liquid cleaning, the surface of the wafer W may be further subjected to non-contact cleaning using a chemical liquid by: supplying a chemical liquid to the surface of the wafer W from the non-contact cleaning chemical liquid supply section 44a after, before, or during the contact cleaning of the surface of the wafer W using the chemical liquid with the first roll cleaning member 41a; and swinging the megasonic nozzle 43 in a direction parallel to the surface of the wafer W wetted with the chemical liquid, with the swing arm 43a, while spraying the liquid excited by the ultrasonic vibrator from the megasonic nozzle 43 toward the center of the wafer W.

As yet another example of chemical liquid cleaning, as shown in FIG. 3, the surface of the wafer W may be subjected to non-contact cleaning using a chemical liquid by: keeping the roll cleaning member 41 placed outside the wafer W, rotating the wafer W supported by the rotation support section 40, and supplying a chemical liquid to the surface of the wafer W from the non-contact cleaning chemical liquid supply section 44a; and swinging the megasonic nozzle 43 in a direction parallel to the surface of the wafer W wetted with the chemical liquid, with the swing arm 43a, while spraying the liquid excited by the ultrasonic vibrator from the megasonic nozzle 43 toward the center of the wafer W.

After the cleaning of the surface of the wafer W with the chemical liquid is completed, the chemical liquid is washed away from the surface of the wafer W by: setting the first roll cleaning member 41a apart from the surface of the wafer W when the first roll cleaning member 41a has been used for chemical liquid cleaning; and supplying a rinsing liquid from the first to third rinsing liquid nozzles 42a1 to 42a3 to the surface of the wafer W.

Next, the surface of the wafer W is cleaned with an organic solvent. As an example of organic solvent cleaning, as shown in FIG. 5A, the surface of the wafer W is subjected to contact cleaning using an organic solvent with the second roll cleaning member 41b by: keeping the wafer W supported and rotated by the rotation support section 40; moving the second roll cleaning member 41b to a position over the radius of the wafer W; supplying an organic solvent to the surface of the wafer W from the first organic solvent nozzle 42c1 and the second organic solvent nozzle 42c2; and pressing the second roll cleaning member 41b against the surface of the wafer W with the surface of the wafer W being wetted with the organic solvent, while the second roll cleaning member 41b is rotated about the central axis. At this time, as shown in FIG. 5B, the roll holding section 41d is tilted so that the first roll cleaning member 41a is placed at a higher height position than the second roll cleaning member 41b, and the first roll cleaning member 41a is not pressed against the surface of the wafer W but is spaced apart from the surface.

As another example of organic solvent cleaning, the surface of the wafer W may be further subjected to non-contact cleaning using an organic solvent by: supplying an organic solvent to the surface of the wafer W from the non-contact cleaning organic solvent supply section 44b after, before, or during the contact cleaning of the surface of the wafer W using the organic solvent with the second roll cleaning member 41b; and swinging the megasonic nozzle 43 in a direction parallel to the surface of the wafer W wetted with the organic solvent, with the swing arm 43a, while spraying the liquid excited by the ultrasonic vibrator from the megasonic nozzle 43 toward the center of the wafer W.

As yet another example of organic solvent cleaning, the surface of the wafer W may be subjected to non-contact cleaning using an organic solvent by: keeping the wafer W supported and rotated by the rotation support section 40; supplying an organic solvent to the surface of the wafer W from the non-contact cleaning organic solvent supply section 44b; and swinging the megasonic nozzle 43 in a direction parallel to the surface of the wafer W wetted with the organic solvent, with the swing arm 43a, while spraying the liquid excited by the ultrasonic vibrator from the megasonic nozzle 43 toward the center of the wafer W.

After the cleaning of the surface of the wafer W with the organic solvent is completed, the organic solvent is washed away from the surface of the wafer W by: setting the second roll cleaning member 41b apart from the surface of the wafer W when the second roll cleaning member 41b has been used for organic solvent cleaning; and supplying a rinsing liquid from the first to third rinsing liquid nozzles 42a1 to 42a3 to the surface of the wafer W.

According to the embodiment described above, cleaning the wafer sequentially using both a chemical liquid other than an organic solvent and an organic solvent in one unit makes it possible to reliably dissolve and remove the organic residues on the surface of the wafer W without increasing the size of the entire apparatus while maintaining the cleaning effect of the conventional chemical liquid.

### (Another Example of First Cleaning Module)

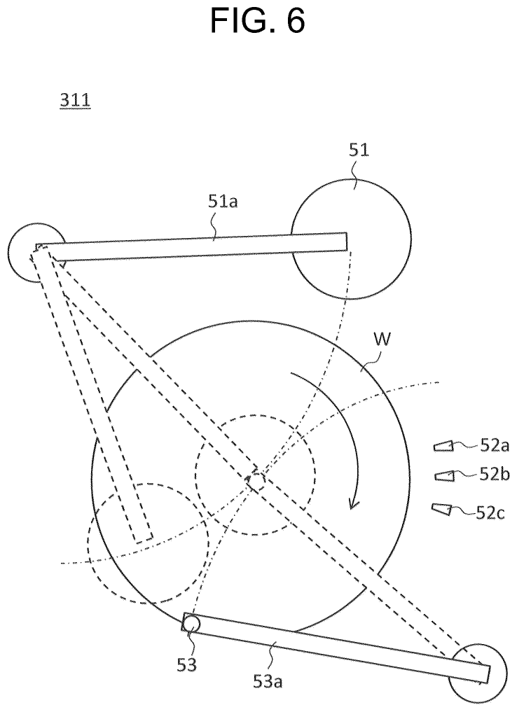

Next, with reference to FIG. 6, another example of the cleaning apparatus included in the first cleaning module 311 will be described. FIG. 6 is a plan view showing a schematic configuration of another example of the cleaning apparatus included in the first cleaning module 311.

As shown in FIG. 6, the cleaning apparatus 311 includes: a rotation support section (not shown) that supports and rotates the wafer W, a rinsing liquid supply section 52a that supplies a rinsing liquid such as ultrapure water (DIW) to the surface of the wafer W; a chemical liquid supply section 52b that supplies a chemical liquid other than an organic solvent to the surface of the wafer W in which the chemical liquid is, for example, ammonia-hydrogen peroxide mixture (SC1), hydrochloric acid-hydrogen peroxide mixture (SC2), sulfuric acid-hydrogen peroxide (SPM), sulfuric acid hydrogen, or hydrofluoric acid; an organic solvent supply section 52c that supplies an organic solvent (for example, dimethyl sulfoxide (DMSO)) to the surface of the wafer W; and cleaning means 51 and 53 that clean the surface of the wafer W supported by the rotation support section 40 using a chemical liquid from the chemical liquid supply section 52b, and then clean the surface of the wafer W using an organic solvent from the organic solvent supply section 52c while the wafer W is kept supported by the rotation support section 40.

In the example shown in FIG. 6, the cleaning means 51 and 53 include a contact cleaning member 51 that comes into contact with the surface of the wafer W to clean the surface, and a non-contact cleaning nozzle 53 that sprays fluid onto the surface of the wafer W to clean the surface.

In the present embodiment, the non-contact cleaning member 53 is a two-fluid jet nozzle that sprays a jet stream containing a mixture of a liquid (for example, CO₂ water or pure water) and a carrier gas (for example, N₂ or CDA). As shown in FIG. 6, the two-fluid jet nozzle 53 is disposed at the head end of a swing arm 53a, and swings in a direction parallel to the surface of the wafer W with the base end portion of the swing arm 53a as a rotating shaft.

Furthermore, in the present embodiment, as shown in FIG. 6, the contact cleaning member 51 is a buff cleaning member that comes into contact with the surface of the wafer W to clean the surface while rotating around a central axis perpendicular to the surface of the wafer W. The buff cleaning member 51 is disposed at the head end of the swing arm 51a, and swings in a direction parallel to the surface of the wafer W with the base end portion of the swing arm 51a as a rotating shaft.

Next, an example of the operation of the cleaning apparatus 311 having the above configuration will be described. First, the surface of the wafer W is cleaned with a chemical liquid. As an example of chemical liquid cleaning, as shown in FIG. 6, the surface of the wafer W is subjected to contact cleaning using a chemical liquid with the buff cleaning member 51 by: keeping the two-fluid jet nozzle 53 placed outside the wafer W, rotating the wafer W supported by the rotation support section, and supplying a chemical liquid to the surface of the wafer W from the chemical liquid supply section 52b; pressing the buff cleaning member 51 against the surface of the wafer W with the surface of the wafer W being wetted with the chemical liquid, while the buff cleaning member 51 is rotated about the central axis; and swinging the buff cleaning member 51 in a direction parallel to the surface of the wafer W with the swing arm 51a. In this case, the buff cleaning member 51 is made of, for example, PVA.

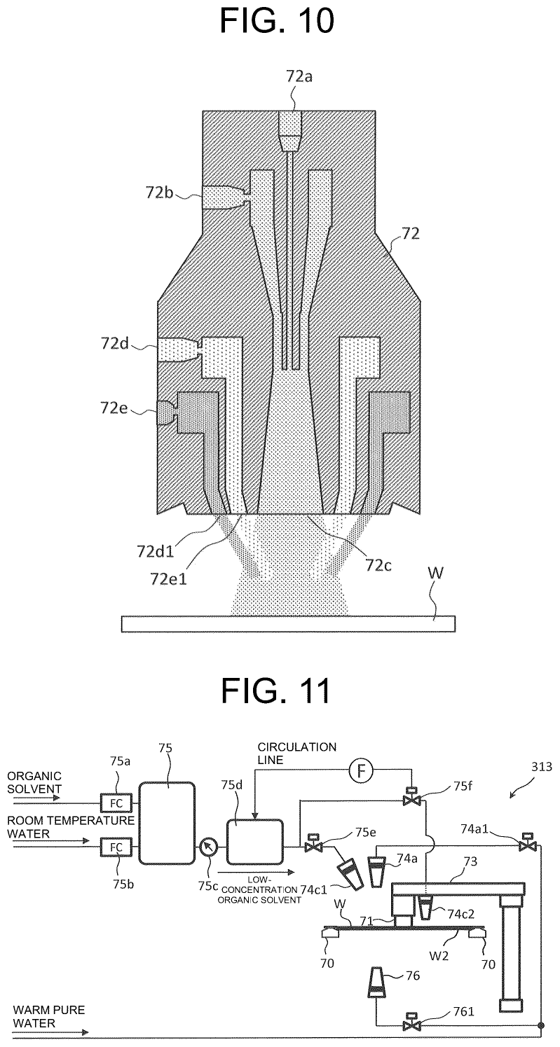

As another example of chemical liquid cleaning, the surface of the wafer W may be further subjected to non-contact cleaning using a chemical liquid (in which the chemical liquid is kept supplied from the chemical liquid supply section 52b to the surface of the wafer W) by: spraying a jet stream containing a mixture of liquid and carrier gas from the two-fluid jet nozzle 53 toward the center of the wafer W after, before, or during the contact cleaning of the surface of the wafer W using the chemical liquid with the buff cleaning member 51; and swinging the two-fluid jet nozzle 53 in a direction parallel to the surface of the wafer W with the swing arm 53a. At this time, as will be described later, there may be a configuration such that a chemical liquid supply section is provided inside the two-fluid jet nozzle 53 (see FIG. 10) and the chemical liquid may be supplied from the inside of the two-fluid jet nozzle 53.

As yet another example of chemical liquid cleaning, as shown in FIG. 6, the surface of the wafer W is subjected to non-contact cleaning using a chemical liquid by: keeping the buff cleaning member 51 placed outside the wafer W, rotating the wafer W supported by the rotation support section 40, and supplying a chemical liquid to the surface of the wafer W from the chemical liquid supply section 52b; spraying a jet stream containing a mixture of liquid and carrier gas from the two-fluid jet nozzle 53 toward the center of the wafer W with the surface of the wafer W being wetted with the chemical liquid; and swinging the two-fluid jet nozzle 53 in a direction parallel to the surface of the wafer W with the swing arm 53a. At this time, as will be described later, there may be a configuration such that a chemical liquid supply section is provided inside the two-fluid jet nozzle 53 (see FIG. 10) and the chemical liquid may be supplied from the inside of the two-fluid jet nozzle 53.

After the cleaning of the surface of the wafer W with the chemical liquid is completed, the chemical liquid is washed away from the surface of the wafer W by: setting the buff cleaning member 51 apart from the surface of the wafer W when the buff cleaning member 51 has been used for chemical liquid cleaning; and supplying a rinsing liquid from the rinsing liquid supply section 52a to the surface of the wafer W.

Next, the surface of the wafer W is cleaned with an organic solvent. As an example of organic solvent cleaning, as shown in FIG. 6, the surface of the wafer W is subjected to non-contact cleaning using an organic solvent by: keeping the wafer W supported and rotated by the rotation support section; moving the buff cleaning member 51 to the outside of the wafer W; supplying an organic solvent to the surface of the wafer W from the organic solvent supply section 52c; spraying a jet stream containing a mixture of liquid and carrier gas from the two-fluid jet nozzle 53 toward the center of the wafer W with the surface of the wafer W being wetted with the organic solvent; and swinging the two-fluid jet nozzle 53 in a direction parallel to the surface of the wafer W with the swing arm 53a. At this time, as will be described later, there may be a configuration such that an organic solvent supply section is provided inside the two-fluid jet nozzle 53 (see FIG. 10) and the organic solvent may be supplied from the inside of the two-fluid jet nozzle 53.

As another example of organic solvent cleaning, as shown in FIG. 6, the surface of the wafer W may be further subjected to contact cleaning using an organic solvent with the buff cleaning member 51 by: pressing the buff cleaning member 51 against the surface of the wafer W while the buff cleaning member 51 is rotated about the central axis after, before, or during the non-contact cleaning of the surface of the wafer W using the organic solvent with the two-fluid jet nozzle 53; and swinging the buff cleaning member 51 in a direction parallel to the surface of the wafer W with the swing arm 51a. In this case, the buff cleaning member 51 is made of, for example, PTFE.

As yet another example of organic solvent cleaning, as shown in FIG. 6, the surface of the wafer W may be subjected to contact cleaning using an organic solvent with the buff cleaning member 51 by: keeping the wafer W supported and rotated by the rotation support section; moving the two-fluid jet nozzle 53 to the outside of the wafer W; supplying an organic solvent to the surface of the wafer W from the organic solvent supply section 52c; pressing the buff cleaning member 51 against the surface of the wafer W with the surface of the wafer W being wetted with the organic solvent, while the buff cleaning member 51 is rotated about the central axis; and swinging the buff cleaning member 51 in a direction parallel to the surface of the wafer W with the swing arm 51a.

After the cleaning of the surface of the wafer W with the organic solvent is completed, the organic solvent is washed away from the surface of the wafer W by: setting the buff cleaning member 51 apart from the surface of the wafer W when the buff cleaning member 51 has been used for organic solvent cleaning; and supplying a rinsing liquid from the rinsing liquid supply section 52a to the surface of the wafer W.

Note that a chemical liquid or an organic solvent during buff cleaning may be supplied through a liquid supply line (not shown) attached along the swing arm 51a and connected to the center hole of the buff cleaning member 51.

According to the embodiment described above, cleaning the wafer sequentially using both a chemical liquid other than an organic solvent and an organic solvent in one unit makes it possible to reliably dissolve and remove the organic residues on the surface of the wafer W without increasing the size of the entire apparatus while maintaining the cleaning effect of the conventional chemical liquid.

### (Second Cleaning Module)

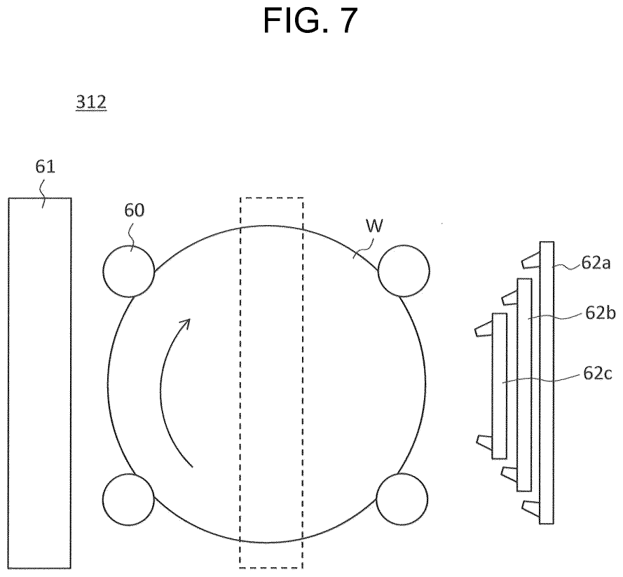

Next, with reference to FIG. 7, the configuration of a cleaning apparatus included in the second cleaning module 312 will be described. FIG. 7 is a plan view showing a schematic configuration of an example of the cleaning apparatus included in the second cleaning module 312.

As shown in FIG. 7, the cleaning apparatus 312 includes: a rotation support section 60 that supports and rotates the wafer W; a rinsing liquid supply section 62a that supplies a rinsing liquid such as ultrapure water (DIW) to the surface of the wafer W; a chemical liquid supply section 62b that supplies a chemical liquid other than an organic solvent to the surface of the wafer W in which the chemical liquid is, for example, ammonia-hydrogen peroxide mixture (SC1), hydrochloric acid-hydrogen peroxide mixture (SC2), sulfuric acid-hydrogen peroxide (SPM), sulfuric acid hydrogen, or hydrofluoric acid; an organic solvent supply section 62c that supplies an organic solvent (for example, dimethyl sulfoxide (DMSO)) to the surface of the wafer W; and cleaning means 61 that cleans the surface of the wafer W supported by the rotation support section 60 using a chemical liquid from the chemical liquid supply section 62b, and then clean the surface of the wafer W using an organic solvent from the organic solvent supply section 62c while the wafer W is kept supported by the rotation support section 60.

Of these, the rotation support section 60 has a plurality of (four in the illustrated example) rotating rollers that come into contact with the outer circumferential portion of the wafer W to support it. When each rotating roller rotates around the central shaft (counterclockwise in the illustrated example), the rotational force of each rotating roller is transmitted to the outer circumferential portion of the wafer W and the wafer W is rotated around the central shaft (clockwise in the illustrated example).

In the example shown in FIG. 7, the cleaning means 61 is a contact cleaning member that comes into contact with the surface of the wafer W to clean the surface. More specifically, the cleaning means 61 is a roll cleaning member that comes into contact with the surface of the wafer W to clean the surface while rotating around a central axis parallel to the surface of the wafer W. The roll cleaning member 61 is moved between a cleaning position over the center of the wafer W and a retracting position outside the wafer W by a moving mechanism (not shown). The configuration of the roll cleaning member 61 is similar to that of the roll cleaning member 41 described with reference to FIGS. 4A, 4B, 5A and 5B, and detailed description thereof will be omitted here.

Next, an example of the operation of the cleaning apparatus 312 having the above configuration will be described. First, as shown in FIG. 7, the deposits of non-organic matter on the surface of the wafer W are dissolved in the chemical liquid and removed by keeping the roll cleaning member 61 placed outside the wafer W, rotating the wafer W supported by the rotation support section 60, and supplying the chemical liquid from the chemical liquid supply section 62b to the surface of the wafer W and wetting the surface of the wafer W with the chemical liquid.

At this time, the surface of the wafer W may be further subjected to contact cleaning using a chemical liquid with the first roll cleaning member 41a by: moving the first roll cleaning member 41a (see FIG. 4A) of the roll cleaning member 61 to a position over the radius of the wafer W; and pressing the first roll cleaning member 41a against the surface of the wafer W while the first roll cleaning member 41a is rotated about the central axis. At this time, as shown in FIG. 4B, the roll holding section 41d is tilted so that the second roll cleaning member 41b is placed at a higher height position than the first roll cleaning member 41a, and the second roll cleaning member 41b is not pressed against the surface of the wafer W but is spaced apart from the surface.

After the cleaning of the surface of the wafer W with the chemical liquid is completed, the chemical liquid is washed away from the surface of the wafer W by supplying a rinsing liquid from the rinsing liquid supply section 62a to the surface of the wafer W.

Next, the surface of the wafer W is subjected to contact cleaning using an organic solvent with the second roll cleaning member 41b by: keeping the wafer W supported and rotated by the rotation support section 60; supplying an organic solvent to the surface of the wafer W from the organic solvent supply section 62c; moving the second roll cleaning member 41b (see FIG. 5A) of the roll cleaning member 61 to a position over the radius of the wafer W with the surface of the wafer W being wetted with the organic solvent; and pressing the second roll cleaning member 41b against the surface of the wafer W while the second roll cleaning member 41b is rotated about the central axis. At this time, as shown in FIG. 5B, the roll holding section 41d is tilted so that the first roll cleaning member 41a is placed at a higher height position than the second roll cleaning member 41b, and the first roll cleaning member 41a is not pressed against the surface of the wafer W but is spaced apart from the surface.

After the cleaning of the surface of the wafer W with the organic solvent is completed, the organic solvent is washed away from the surface of the wafer W by: setting the roll cleaning member 61 apart from the surface of the wafer W; and supplying a rinsing liquid from the rinsing liquid supply section 62a to the surface of the wafer W.

According to the embodiment described above, cleaning the wafer sequentially using both a chemical liquid other than an organic solvent and an organic solvent in one unit makes it possible to reliably dissolve and remove the organic residues on the surface of the wafer W without increasing the size of the entire apparatus while maintaining the cleaning effect of the conventional chemical liquid.

### (Third Cleaning Module)

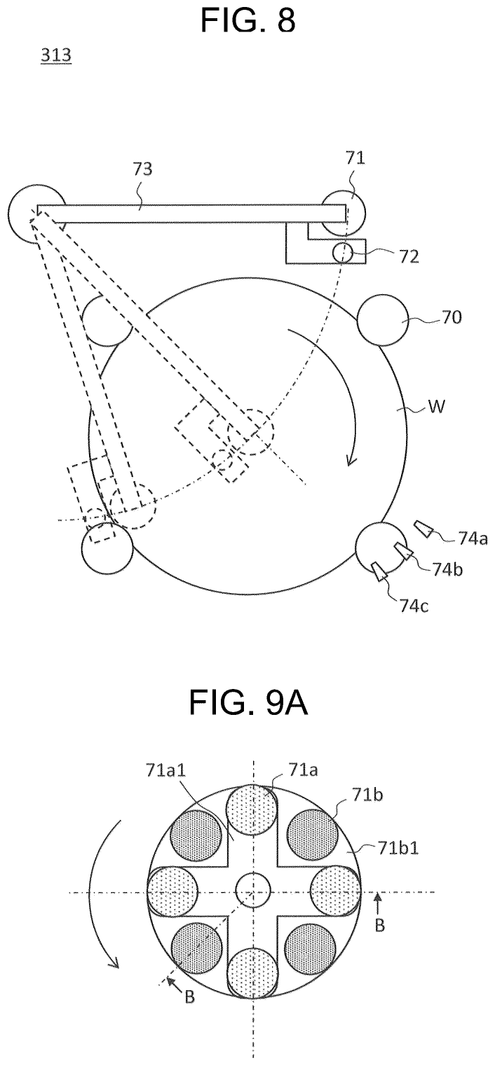

Next, with reference to FIG. 8, the configuration of a cleaning apparatus included in the third cleaning module 313 will be described. FIG. 8 is a plan view showing a schematic configuration of an example of the cleaning apparatus included in the third cleaning module 313.

As shown in FIG. 8, the cleaning apparatus 313 includes: a rotation support section 70 that supports and rotates the wafer W; a rinsing liquid supply section 74a that supplies a rinsing liquid such as ultrapure water (DIW) to the surface of the wafer W; a chemical liquid supply section 74b that supplies a chemical liquid other than an organic solvent to the surface of the wafer W in which the chemical liquid is, for example, ammonia-hydrogen peroxide mixture (SC1), hydrochloric acid-hydrogen peroxide mixture (SC2), sulfuric acid-hydrogen peroxide (SPM), sulfuric acid hydrogen, or hydrofluoric acid; an organic solvent supply section 74c that supplies an organic solvent (for example, dimethyl sulfoxide (DMSO)) to the surface of the wafer W; and cleaning means 71 and 72 that clean the surface of the wafer W supported by the rotation support section 70 using a chemical liquid from the chemical liquid supply section 62b, and then clean the surface of the wafer W using an organic solvent from the organic solvent supply section 72c while the wafer W is kept supported by the rotation support section 70.

Of these, the rotation support section 70 has a plurality of (four in the illustrated example) rotating rollers that come into contact with the outer circumferential portion of the wafer W to support the wafer W. When each rotating roller rotates around the central shaft (counterclockwise in the illustrated example), the rotational force of each rotating roller is transmitted to the outer circumferential portion of the wafer W and the wafer W is rotated around the central shaft (clockwise in the illustrated example). Note that the rotation support section 70 may be a chuck type rotation support section that grips the outer circumferential portion of the wafer W with a plurality of claw members and rotates the claw members about the central shaft.

In the example shown in FIG. 8, the cleaning means 71 and 72 include a contact cleaning member 71 that comes into contact with the surface of the wafer W to clean the surface, and a non-contact cleaning nozzle 72 that sprays fluid onto the surface of the wafer W to clean the surface.

In the present embodiment, the contact cleaning means 71 is a pen cleaning member that comes into contact with the surface of the wafer W to clean the surface while rotating around a central axis perpendicular to the surface of the wafer W. The non-contact cleaning means 72 is a two-fluid jet nozzle that sprays a jet stream containing a mixture of a liquid (for example, CO₂ water or pure water) and a carrier gas (for example, N₂ or CDA). The pen cleaning member 71 and the two-fluid jet nozzle 72 are disposed at the head end of a swing arm 73, and swings in a direction parallel to the surface of the wafer W with the base end portion of the swing arm 73 as a rotating shaft.

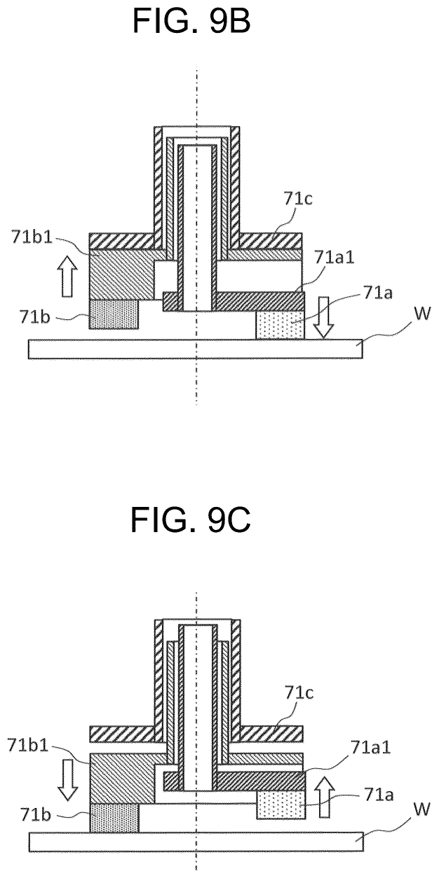

An example of the configuration of the pen cleaning member 71 will be described in detail with reference to FIGS. 9A to 9C. FIG. 9A is a plan view of the pen cleaning member 71 seen from below, and FIGS. 9B and 9C are internal side views of the pen cleaning member 71.

As shown in FIGS. 9A to 9C, the pen cleaning member 71 includes: a plurality of (each four in the illustrated example) first pen cleaning members 71a and second pen cleaning members 71b; a first pen support section 71a1 and a second pen support section 71b1 that respectively support the first pen cleaning members 71a and the second pen cleaning members 71b; and a holder 71c.

Of these, each first pen cleaning member 71a is, for example, a cylindrical sponge made of PVA (polyvinyl alcohol). Each second pen cleaning member 71b is, for example, a cylindrical sponge made of PTFE (polytetrafluoroethylene). As shown in FIG. 9A, the first pen cleaning members 71a and the second pen cleaning members 71b are placed alternately on the same circumference centered on the rotation axis in a plan view. The first pen cleaning members 71a are fixed to the lower surface of the first pen support section 71a1, and the second pen cleaning members 71b are fixed to the lower surface of the second pen support section 71b1. In other words, the first pen cleaning members 71a and the second pen cleaning members 71b are coaxially disposed and supported on the same swing arm 73 in a plan view.

As shown in FIGS. 9B and 9C, the first pen support section 71a1, the second pen support section 71b1, and the holder 71c all have a cylindrical portion that extends vertically upward coaxially with the central shaft. The cylindrical portion of the second pen support section 71b1 is disposed so as to be coaxially inserted inside the cylindrical portion of the holder 71c. The cylindrical portion of the first pen support section 71a1 is disposed so as to be coaxially inserted inside the cylindrical portion of the second pen support section 71b1. Thereby, the first pen support section 71a1 and the second pen support section 71b1 can move up and down with respect to the holder 71c independently of each other. As shown in FIG. 9B, lowering the first pen support section 71a1 and raising the second pen support section 71b1 presses the first pen cleaning members 71a against the surface of the wafer W with the second pen cleaning members 71b being spaced apart from the surface of the wafer W. Furthermore, as shown in FIG. 9C, raising the first pen support section 71a1 and lowering the second pen support section 71b1 presses the second pen cleaning members 71b against the surface of the wafer W with the first pen cleaning members 71a being spaced apart from the surface of the wafer W. This makes it possible to use different sponges in chemical liquid cleaning and organic solvent cleaning.

Next, an example of the configuration of the two-fluid jet nozzle 72 will be described in detail with reference to FIG. 10. FIG. 10 is an internal side view of the two-fluid jet nozzle 72.

As shown in FIG. 10, the two-fluid jet nozzle 72 includes: a liquid introduction port 72a that introduces a liquid (for example, CO₂ water or pure water); a gas introduction port 72b that introduces a carrier gas (for example, N₂ or CDA); and a jet stream spraying port 72c communicating with both the liquid introduction port 72a and the gas introduction port 72b. The liquid introduced from the liquid introduction port 72a and the carrier gas introduced from the gas introduction port 72b are mixed inside the two-fluid jet nozzle 72 so as to be sprayed as a jet stream from a jet stream spraying port 72c provided on the bottom surface of the two-fluid jet nozzle 72.

In the present embodiment, as shown in FIG. 10, the two-fluid jet nozzle 72 is further provided with a chemical liquid introduction port 72d and a chemical liquid discharge port 72d1 communicating with the chemical liquid introduction port 72d. The chemical liquid discharge port 72d1 is disposed on the bottom surface of the two-fluid jet nozzle 72 so as to be adjacent to the jet stream spraying port 72c. The chemical liquid introduced from the chemical liquid introduction port 72d is discharged from the chemical liquid discharge port 72d1 toward the jet stream sprayed from the jet stream spraying port 72c, is mixed with the jet stream outside the two-fluid jet nozzle 72, and then supplied to the surface of the wafer W. Mixing the chemical liquid and the jet stream outside the two-fluid jet nozzle 72 allows the chemical liquid to be supplied from the two-fluid jet nozzle 72 without being affected by the pressure and flow rate of the carrier gas introduced from the gas introduction port 72b. As a modification, the chemical liquid introduced from the chemical liquid introduction port 72d may be mixed inside the two-fluid jet nozzle 72 with the liquid introduced from the liquid introduction port 72a and the carrier gas introduced from the gas introduction port 72b.

Furthermore, in the present embodiment, as shown in FIG. 10, the two-fluid jet nozzle 72 is further provided with an organic solvent introduction port 72e and an organic solvent discharge port 72e1 communicating with the organic solvent introduction port 72e. The organic solvent discharge port 72e1 is disposed on the bottom surface of the two-fluid jet nozzle 72 so as to be adjacent to the jet stream spraying port 72c. The chemical liquid introduced from the organic solvent introduction port 72e is discharged from the organic solvent discharge port 72e1 toward the jet stream sprayed from the jet stream spraying port 72c, is mixed with the jet stream outside the two-fluid jet nozzle 72, and then supplied to the surface of the wafer W. Mixing the organic solvent and the jet stream outside the two-fluid jet nozzle 72 allows the organic solvent to be supplied from the two-fluid jet nozzle 72 without being affected by the pressure and flow rate of the carrier gas introduced from the gas introduction port 72b. As a modification, the organic solvent introduced from the organic solvent introduction port 72e may be mixed inside the two-fluid jet nozzle 72 with the liquid introduced from the liquid introduction port 72a and the carrier gas introduced from the gas introduction port 72b.

Next, with reference to FIG. 11, an example of piping of the cleaning apparatus 313 shown in FIG. 8 will be described. As shown in FIG. 11, the cleaning apparatus 313 includes a dilution module 75 that dilutes an organic solvent by mixing water (at room temperature), and a back surface rinsing liquid supply section 76 that supplies warm pure water to the back surface of the wafer W.

As shown in FIG. 11, an organic solvent supply source (not shown) and a water source (not shown) are connected to the upstream side of the dilution module 75 via flow rate controllers 75a and 75b, respectively. Appropriately controlling the flow rate controllers 75a and 75b generates a low-concentration organic solvent diluted to a desired concentration (for example, a concentration that is unlikely to deteriorate the casing of the cleaning apparatus), in the dilution module 75. A pressure gauge 75c and a low concentration organic solvent storage module 75d are connected to the downstream side of the dilution module 75. The low concentration organic solvent storage module 75d is connected to a first nozzle 74c1 and a second nozzle 74c2 of the organic solvent supply section 74c via solenoid valves 75e and 75f, respectively. In the illustrated example, the second nozzle 74c2 is fixedly supported by the swing arm 73 so as to be swung together with the pen cleaning member 71 when the pen cleaning member 71 is swung in a direction parallel to the surface of the wafer W by the swing arm 73. When the solenoid valves 75e and 75f are opened, a low-concentration organic solvent is supplied toward the surface of the wafer W from the first nozzle 74c1 and the second nozzle 74c2, respectively. When the solenoid valves 75e and 75f are closed, the supply of organic solvent from the first nozzle 74c1 and the second nozzle 74c2 is stopped.

In the illustrated example, a circulation line is provided between the solenoid valve 75f of the second nozzle 74c2 and the low concentration organic solvent storage module 75d. This causes the low-concentration organic solvent flowing from the low concentration organic solvent storage module 75d toward the second nozzle 74c2 to return to the low concentration organic solvent storage module 75d through the circulation line when the solenoid valve 75f is closed.

The rinsing liquid supply section 74a and the back surface rinsing liquid supply section 76 are connected to a warm pure water source (not shown) via solenoid valves 74a1 and 761, respectively. When the solenoid valves 74a1 and 761 are opened, warm pure water is supplied from the rinsing liquid supply section 74a and the back surface rinsing liquid supply section 76 respectively toward the front surface and back surface of the wafer W, thereby raising the temperature of the wafer W. When the solenoid valves 74a1 and 761 are closed, the supply of warm pure water from the rinsing liquid supply section 74a and the back surface rinsing liquid supply section 76 is stopped.

Next, an example of the operation of the cleaning apparatus 313 having the above configuration will be described. First, the surface of the wafer W is cleaned with a chemical liquid. As an example of chemical liquid cleaning, as shown in FIG. 8, the surface of the wafer W is subjected to contact cleaning using a chemical liquid with the first pen cleaning members 71a by: rotating the wafer W supported by the rotation support section 40, and supplying a chemical liquid to the surface of the wafer W from the chemical liquid supply section 74b; pressing the first pen cleaning members 71a against the surface of the wafer W with the surface of the wafer W being wetted with the chemical liquid, while the pen cleaning member 71 is rotated about the central axis; and swinging the pen cleaning member 71 and the two-fluid jet nozzle 72 in a direction parallel to the surface of the wafer W with the swing arm 73. At this time, as shown in FIG. 9B, the second pen support section 71b1 is raised, and the second pen cleaning members 71b are not pressed against the surface of the wafer W but are spaced apart from the surface.

As another example of chemical liquid cleaning, the surface of the wafer W may be further subjected to non-contact cleaning using a chemical liquid (in which the chemical liquid is kept supplied from the chemical liquid supply section 74b when non-contact cleaning is performed after pen cleaning) by: spraying a jet stream containing a mixture of liquid and carrier gas from the two-fluid jet nozzle 72 toward the center of the wafer W after, before, or during the contact cleaning of the surface of the wafer W using the chemical liquid with the first pen cleaning members 71a. At this time, as shown in FIG. 10, when the two-fluid jet nozzle 72 is provided with a chemical liquid discharge port 72d1, or when the two-fluid jet nozzle 72 is provided with a chemical liquid supply section inside, a jet stream containing a chemical liquid may be supplied to the surface of the wafer W by the two-fluid jet nozzle 72.

As yet another example of chemical liquid cleaning, as shown in FIG. 8, the surface of the wafer W is subjected to non-contact cleaning using a chemical liquid by: keeping the pen cleaning member 71 spaced apart from the surface of the wafer W, rotating the wafer W supported by the rotation support section 40, and supplying a chemical liquid to the surface of the wafer W from the chemical liquid supply section 52b; spraying a jet stream containing a mixture of liquid and carrier gas from the two-fluid jet nozzle 72 toward the center of the wafer W with the surface of the wafer W being wetted with the chemical liquid; and swinging the pen cleaning member 71 and the two-fluid jet nozzle 72 in a direction parallel to the surface of the wafer W with the swing arm 73. At this time, as shown in FIG. 10, when the two-fluid jet nozzle 72 is provided with a chemical liquid discharge port 72d1, or when the two-fluid jet nozzle 72 is provided with a chemical liquid supply section inside, a jet stream containing a chemical liquid may be supplied to the surface of the wafer W by the two-fluid jet nozzle 72.

After the cleaning of the surface of the wafer W with the chemical liquid is completed, the chemical liquid is washed away from the surface of the wafer W and the temperature of the wafer W is raised by: setting the first pen cleaning members 71a apart from the surface of the wafer W when the first pen cleaning members 71a have been used for chemical liquid cleaning; and supplying a rinsing liquid (warm pure water) from the rinsing liquid supply section 74a to the surface of the wafer W.

Next, the surface of the wafer W is cleaned with an organic solvent. As an example of organic solvent cleaning, as shown in FIG. 8, the surface of the wafer W is subjected to non-contact cleaning using an organic solvent by: keeping the wafer W supported and rotated by the rotation support section; supplying a (low-concentration) organic solvent to the surface of the wafer W from the organic solvent supply section 74c; spraying a jet stream containing a mixture of liquid and carrier gas from the two-fluid jet nozzle 72 toward the center of the wafer W with the surface of the wafer W being wetted with the (low-concentration) organic solvent; and swinging the pen cleaning member 71 and the two-fluid jet nozzle 72 in a direction parallel to the surface of the wafer W with the swing arm 73. At this time, as shown in FIG. 10, when the two-fluid jet nozzle 72 is provided with an organic solvent discharge port 72e1, or when the two-fluid jet nozzle 72 is provided with an organic solvent supply section inside, a jet stream containing an organic solvent may be supplied to the surface of the wafer W by the two-fluid jet nozzle 72. Using a two-fluid jet nozzle 72 as shown in FIG. 10 makes it possible to selectively supply a jet stream containing a chemical liquid and a jet stream containing an organic solvent. This allows the cleaning apparatus to be more compact and less costly compared to a case in which a two-fluid jet nozzle is provided for each solution.

In the present embodiment, the organic solvent supplied to the surface of the wafer W is diluted to a concentration that is unlikely to deteriorate the casing of the cleaning apparatus, but the temperature of the wafer W is raised in advance by warm pure water supplied from the rinsing liquid supply section 74a. This makes it possible to heat, by the heat of the wafer W, the (low-concentration) organic solvent supplied from the organic solvent supply section 74c to the surface of the wafer W, thereby improving the cleaning performance.

The temperature of the wafer W may be further raised by supplying warm pure water to the back surface of the wafer W from the back surface rinsing liquid supply section 76 while the front surface of the wafer W is subjected to non-contact cleaning using an organic solvent with the two-fluid jet nozzle 72. In this case, the heat of the wafer W heats the (low-concentration) organic solvent supplied from the organic solvent supply section 74c to the surface of the wafer W, allowing improved cleaning performance. The supply of warm pure water from the back surface rinsing liquid supply section 76 to the back surface of the wafer W can be combined with all embodiments in which an organic solvent is supplied to the front surface of the wafer W.

As another example of organic solvent cleaning, the surface of the wafer W may be further subjected to contact cleaning using an organic solvent by: pressing the second pen cleaning members 71b against the surface of the wafer W while the pen cleaning member 71 is rotated about the central axis after, before, or during the non-contact cleaning of the surface of the wafer W using the organic solvent with the two-fluid jet nozzle 72. When pen cleaning using a chemical liquid is not performed, the first pen cleaning members 71a are unnecessary, and therefore the organic solvent cleaning may be performed using a single type of pen cleaning members 71b.

As yet another example of organic solvent cleaning, the surface of the wafer W is subjected to contact cleaning using an organic solvent with the second pen cleaning members 71b by: keeping the wafer W supported and rotated by the rotation support section 40; and pressing the second pen cleaning members 71b against the surface of the wafer W while the pen cleaning member 71 is rotated about the central axis without spraying a jet stream from the two-fluid jet nozzle 72.

After the cleaning of the surface of the wafer W with the organic solvent is completed, the organic solvent is washed away from the surface of the wafer W by: setting the second pen cleaning members 71b apart from the surface of the wafer W when the second pen cleaning members 71b have been used for organic solvent cleaning; and supplying a rinsing liquid from the rinsing liquid supply section 74c to the surface of the wafer W.

According to the embodiment described above, cleaning the wafer sequentially using both a chemical liquid other than an organic solvent and an organic solvent in one unit makes it possible to reliably dissolve and remove the organic residues on the surface of the wafer W without increasing the size of the entire apparatus while maintaining the cleaning effect of the conventional chemical liquid.

The inventors of the present invention has conducted intensive studies to realize a cleaning apparatus that sequentially uses both a chemical liquid other than an organic solvent and an organic solvent in one unit. Then, the inventors has designed to use an organic solvent with as low a concentration as possible and heat the low-concentration organic solvent instead to improve cleaning performance because organic solvents are expensive and typical casings of cleaning apparatuses do not have sufficient organic solvent resistance. However, since organic solvents easily volatilize, direct heating in a supply tank requires explosion-proof measures, resulting in a high cost.

In contrast, according to the embodiments described above, the temperature of the wafer W can be raised by supplying warm pure water to the back surface of the wafer W from the rinsing liquid supply section 74a and/or the back surface rinsing liquid supply section 76. As a result, even if the organic solvent supplied from the organic solvent supply section 74c to the surface of the wafer W is diluted to a concentration that is unlikely to deteriorate the casing of the cleaning apparatus, the organic solvent is safely heated by the heat of the wafer W, to allow cleaning performance to be improved.

### (Fourth Cleaning Module)

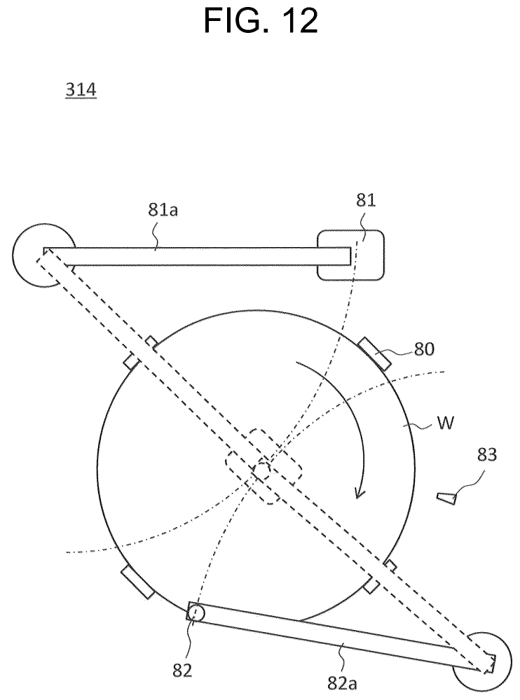

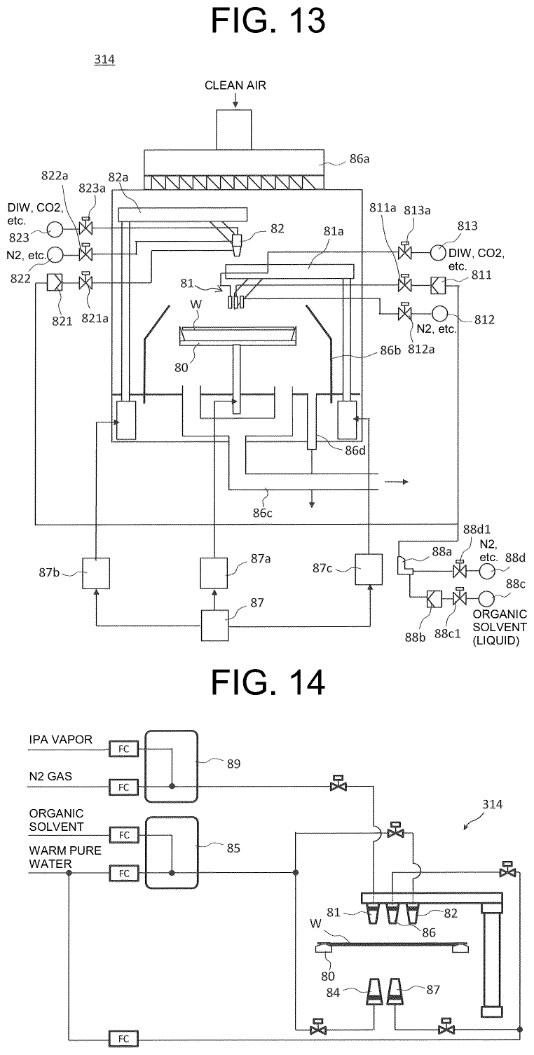

Next, the configuration of a cleaning apparatus included in the fourth cleaning module 314 will be described with reference to FIGS. 12 and 13. FIG. 12 is a plan view showing a schematic configuration of an example of a cleaning apparatus included in the fourth cleaning module 314, and FIG. 13 is a diagram for describing an example of piping of the cleaning apparatus.

As shown in FIGS. 12 and 13, the cleaning apparatus 314 includes: a rotation support section 80 that supports and rotates the wafer W; an organic solvent supply section 83 that supplies an organic solvent (for example, isopropyl alcohol (IPA)) to the surface of the wafer W; a non-contact cleaning nozzle 82 that sprays fluid onto the surface of the wafer W supported by the rotation support section 80 to clean the surface when the organic solvent is supplied from the organic solvent supply section 83; and a drying nozzle 81 that sprays vapor of the organic solvent (IPA) to dry the surface of the wafer W, with the wafer W kept supported by the rotation support section 70.

The rotation support section 80 is a chuck type rotation support section that grips the outer circumferential portion of the wafer W with a plurality of claw members and rotates the claw members about the central shaft.

In the present embodiment, the non-contact cleaning nozzle 82 is a two-fluid jet nozzle that sprays a jet stream containing a mixture of a liquid (for example, CO₂ water or ultrapure water) and a carrier gas (for example, N₂). The two-fluid jet nozzle 82 is disposed at the head end of a swing arm 82a, and swings in a direction parallel to the surface of the wafer W with the base end portion of the swing arm 82a as a rotating shaft.

As shown in FIG. 13, a liquid supply source 823 that supplies liquid (for example, CO₂ water or ultrapure water) and a carrier gas supply source 822 that supplies carrier gas (for example N₂) are connected to the two-fluid jet nozzle 82 via solenoid valves 823a and 822a, respectively. Furthermore, the two-fluid jet nozzle 82 is connected to a vaporizer 88a via a solenoid valve 821a and a filter 821. An organic solvent supply source 88c that supplies a liquid organic solvent (IPA, etc.) is connected to the vaporizer 88a via a solenoid valve 88c1 and a filter 88b. Furthermore, a gas supply source 88d that supplies N₂ or the like is connected to the vaporizer 88a via a solenoid valve 88d1. The liquid organic solvent supplied from the organic solvent supply source 88c is vaporized in the vaporizer 88a, and vapor of the organic solvent is supplied to the two-fluid jet nozzle 82 via the filter 821 and the solenoid valve 821a.

In the example shown in FIG. 13, the drying nozzle 81 is a set of three systems of nozzles (a liquid supply nozzle 81a, a drying assist nozzle 81b, and a drying nozzle 81c). A liquid supply source 813 that supplies CO₂ water, ultrapure water, etc. is connected to the liquid supply nozzle 81a via a solenoid valve 813a. A gas supply source 812 that supplies N₂ or the like is connected to the drying assist nozzle 81b via a solenoid valve 812a. Furthermore, the drying nozzle 81c is connected to a vaporizer 88a via a solenoid valve 811a and a filter 811. Vapor of an organic solvent (such as IPA) generated in the vaporizer 88a is supplied to the drying nozzle 81 via a filter 811 and a solenoid valve 811a.

As shown in FIGS. 12 and 13, the drying nozzle 81 is disposed at the head end of the swing arm 81a, and swings in a direction parallel to the surface of the wafer W with the base end portion of the swing arm 81a as the rotating shaft.

As shown in FIG. 13, a filter fan unit 86a is provided on the ceiling of the casing of the cleaning apparatus 314, and an exhaust duct 86c is provided at the bottom portion, forming a flow of clean air inside the casing from the ceiling portion toward the bottom portion. Furthermore, a drain pipe 86d is provided at the bottom portion of the casing.

As shown in FIG. 13, a cleaning arm lifting-lowering and swinging mechanism 87b are connected to the swing arm 82a (cleaning arm) that holds the two-fluid jet nozzle 82. The swing arm 82a is lifted, lowered, and swung together with the two-fluid jet nozzle 82 by the power transmitted from the cleaning arm lifting-lowering and swinging mechanism 87b. Furthermore, a drying arm lifting-lowering and swinging mechanism 87c is connected to the swing arm 81a (drying arm) that holds the drying nozzle 81. The swing arm 81a is lifted, lowered, and swung together with the drying nozzle 81 by the power transmitted from the drying arm lifting-lowering and swinging mechanism 87c. Additionally, the rotation support section 80 is provided with a stage lifting-lowering and rotation drive mechanism 87a. The rotation support section 80 is lifted, lowered, and rotated together with the wafer W by the power transmitted from the stage lifting-lowering and rotation drive mechanism 87a. The cleaning arm lifting-lowering and swinging mechanism 87b, the drying arm lifting-lowering and swinging mechanism 87c, and the stage lifting-lowering and rotation drive mechanism 87a are all controlled according to control signals transmitted from the control section 15.

Next, an example of the operation of the cleaning apparatus 314 having the above configuration will be described. First, as shown in FIG. 12, the surface of the wafer W is subjected to non-contact cleaning using an organic solvent by: rotating the wafer W supported by the rotation support section 80, and supplying an organic solvent to the surface of the wafer W from the organic solvent supply section 83; spraying a jet stream containing a mixture of liquid and carrier gas from the two-fluid jet nozzle 82 toward the center of the wafer W with the surface of the wafer W being wetted with the organic solvent; and swinging the two-fluid jet nozzle 82 in a direction parallel to the surface of the wafer W with the swing arm 82a. At this time, as shown in FIG. 13, when a vaporizer 88a that generates vapor of an organic solvent is connected to the two-fluid jet nozzle 82, vapor of an organic solvent may be sprayed from the two-fluid jet nozzle 82 together with the jet stream.

After the cleaning of the surface of the wafer W with the organic solvent is completed, the two-fluid jet nozzle 82 is moved to the outside of the wafer W. Then, with the wafer W kept supported and rotated by the rotation support section 80, a liquid such as CO₂ water or ultrapure water is first supplied onto the substrate from the liquid supply nozzle 81a. Vapor of an organic solvent is then sprayed from the drying nozzle 81c toward the surface of the wafer W, and the drying nozzle 81 is swung in a direction parallel to the surface of the wafer W by the swing arm 81a. Thereby, the surface of the wafer W is dried with vapor of an organic solvent (IPA vapor drying). The drying assist nozzle 81b is used for supplying N₂ or the like to assist or accelerate drying of the wafer W. Thereafter, the surface of the wafer W may be further subjected to spin drying by centrifugal force caused by the wafer W being rotated at high speed by the rotation support section 80.

According to the embodiment described above, sequentially performing both cleaning and drying using an organic solvent in one unit makes it possible to reliably dissolve and remove the organic residues on the surface of the wafer W without increasing the size of the entire apparatus while maintaining the drying effect of the conventional organic solvent.

### (Another Example of Fourth Cleaning Module)

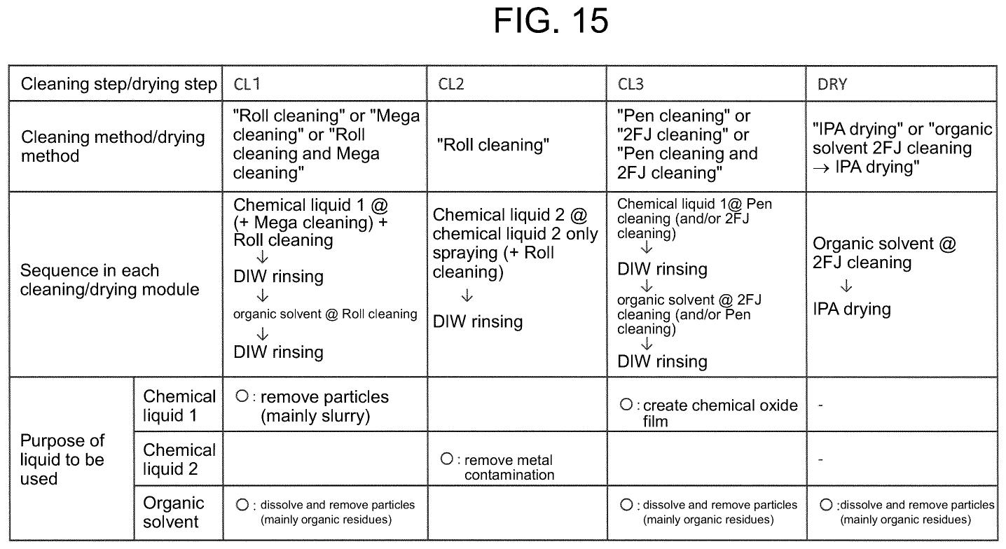

Next, with reference to FIG. 14, another example of the cleaning apparatus included in the fourth cleaning module 314 will be described. FIG. 14 is a plan view showing a schematic configuration of another example of the cleaning apparatus included in the fourth cleaning module 314.

As shown in FIG. 14, the cleaning apparatus 314 includes: a rotation support section 80 that supports and rotates the wafer W; an organic solvent supply section 82 that supplies and cleans an organic solvent (for example, isopropyl alcohol (IPA)) to the surface of the wafer W supported by the rotation support section 80; and a drying nozzle 81 that sprays vapor of the organic solvent (IPA) to dry the surface of the wafer W, with the wafer W kept supported by the rotation support section 70.

In the example shown in FIG. 14, the cleaning apparatus 314 further includes: a gas mixing module 89 that mixes N₂ gas with the vapor of the organic solvent (IPA); a dilution module 85 that dilutes a liquid organic solvent by mixing warm pure water; a back surface organic solvent supply section 84 that supplies an organic solvent diluted with warm pure water to the back surface of the wafer W; and a rinsing liquid supply section 86 and a back surface rinsing liquid supply section 87 that supply warm pure water to the front surface and back surface of the wafer W, respectively.

As shown in FIG. 14, an IPA vapor supply source (not shown) and an N₂ (carrier gas) gas source (not shown) are connected to the upstream side of the gas mixing module 89 via flow rate controllers, respectively. Appropriately controlling the flow rate controller generates IPA vapor with a desired concentration in the gas mixing module 89. The gas mixing module 89 is connected to the drying nozzle 81 via a solenoid valve. When the solenoid valve is opened, IPA vapor is sprayed from the drying nozzle 81 toward the surface of the wafer W. When the solenoid valve is closed, the spraying of IPA vapor from the drying nozzle 81 is stopped.

As shown in FIG. 14, an organic solvent supply source (not shown) and a warm pure water source (not shown) are connected to the upstream side of the dilution module 85 via flow rate controllers, respectively. Appropriately controlling the flow rate controllers generates a low-concentration organic solvent diluted to a desired concentration (for example, a concentration that is unlikely to deteriorate the casing of the cleaning apparatus) in the dilution module 85. The dilution module 85 is connected to the organic solvent supply section 82 and the back surface organic solvent supply section 84 via solenoid valves. When the solenoid valves are opened, organic solvent is supplied from the organic solvent supply section 82 and the back surface organic solvent supply section 84 to the front and back surfaces of the wafer W, respectively. When the solenoid valves are closed, the supply of organic solvent from the organic solvent supply section 82 and the back surface organic solvent supply section 84 is stopped.

Furthermore, the rinsing liquid supply section 86 and the back surface rinsing liquid supply section 87 are connected to a warm pure water source via solenoid valves and a flow rate controllers. When the solenoid valves are opened, warm pure water is supplied from the rinsing liquid supply section 86 and the back surface rinsing liquid supply section 87 toward the front surface and back surface of the wafer W, thereby raising the temperature of the wafer W. When the solenoid valves are closed, the supply of organic solvent from the rinsing liquid supply section 86 and the back surface rinsing liquid supply section 87 is stopped.

Next, an example of the operation of the cleaning apparatus 314 having the above configuration will be described. First, as shown in FIG. 14, the wafer W supported by the rotation support section 40 is rotated, and warm pure water is supplied from the rinsing liquid supply section 86 and the back surface rinsing liquid supply section 87 respectively to the front and back surfaces of the wafer W, thereby raising the temperature of the wafer W.

Next, organic residues on the front and back surfaces of the wafer W are dissolved and removed by the organic solvent by: keeping the wafer W supported and rotated by the rotation support section; a (low-concentration) organic solvent is supplied from the organic solvent supply section 82 and the back surface organic solvent supply section 84 respectively to the front and back surfaces of the wafer W; and wetting the front and back surfaces of the wafer W with the (low-concentration) organic solvent. In the present embodiment, an organic solvent supplied to the front and back surfaces of the wafer W is diluted to a concentration that is unlikely to deteriorate the casing of the cleaning apparatus, but mixing the organic solvent with warm pure water in dilution safely raises the temperature, to allow cleaning performance to be improved. The method of raising the temperature by mixing an organic solvent with warm pure water can be used in combination with all the supply of organic solvents in other embodiments.

Furthermore, in the present embodiment, an organic solvent supplied to the front and back surfaces of the wafer W is diluted to a concentration that is unlikely to deteriorate the casing of the cleaning apparatus, but the temperature of the wafer W is raised in advance by warm pure water supplied from the rinsing liquid supply section 86 and the back surface rinsing liquid supply section 87. Therefore, the heat of the wafer W heats the (low-concentration) organic solvent supplied from the organic solvent supply section 82 and the back surface organic solvent supply section 84 to the front and back surfaces of the wafer W, thereby allowing cleaning performance to be further improved.

After the cleaning of the front and back surfaces of the wafer W with the organic solvent is completed, the surface of the wafer W is dried with vapor of an organic solvent (IPA vapor drying) by: keeping the wafer W supported and rotated by the rotation support section 80; spraying vapor of an organic solvent from the drying nozzle 81 toward the surface of the wafer W; and swinging the drying nozzle 81 in a direction parallel to the surface of the wafer W with the swing arm. Thereafter, the surface of the wafer W may be further subjected to spin drying by centrifugal force caused by the wafer W being rotated at high speed by the rotation support section 80. Note that the wafer W may be dried by supplying a liquid organic solvent to the surface of the wafer W to replace moisture on the surface of the wafer W with the organic solvent, instead of spraying vapor of an organic solvent from the drying nozzle 81.

Also with the embodiments described above, sequentially performing both cleaning and drying using an organic solvent in one unit makes it possible to reliably dissolve and remove the organic residues on the surface of the wafer W without increasing the size of the entire apparatus while maintaining the drying effect of the conventional organic solvent.

The inventors of the present invention has conducted intensive studies to realize a cleaning apparatus that sequentially performs both cleaning and drying using an organic solvent in one unit. Then, the inventors has designed to use an organic solvent with as low a concentration as possible and heat the low-concentration organic solvent instead to improve cleaning performance because organic solvents are expensive and typical casings of cleaning apparatuses do not have sufficient organic solvent resistance. However, since organic solvents easily volatilize, direct heating in a supply tank requires explosion-proof measures, resulting in a high cost.

In contrast, according to the embodiments described above, mixing the organic solvent with warm pure water in dilution safely raises the temperature. This allows cleaning performance to be improved even if the organic solvent supplied to the front and back surfaces of the wafer W is diluted to a concentration that is unlikely to deteriorate the casing of the cleaning apparatus.

Furthermore, according to the present embodiment, the temperature of the wafer W is raised in advance by warm pure water supplied from the rinsing liquid supply section 86 and the back surface rinsing liquid supply section 87. This allows the cleaning performance to be further improved even if the organic solvent supplied to the front and back surfaces of the wafer W is diluted to a concentration that is unlikely to deteriorate the casing of the cleaning apparatus.

### <Cleaning Sequence in the Cleaning Section>

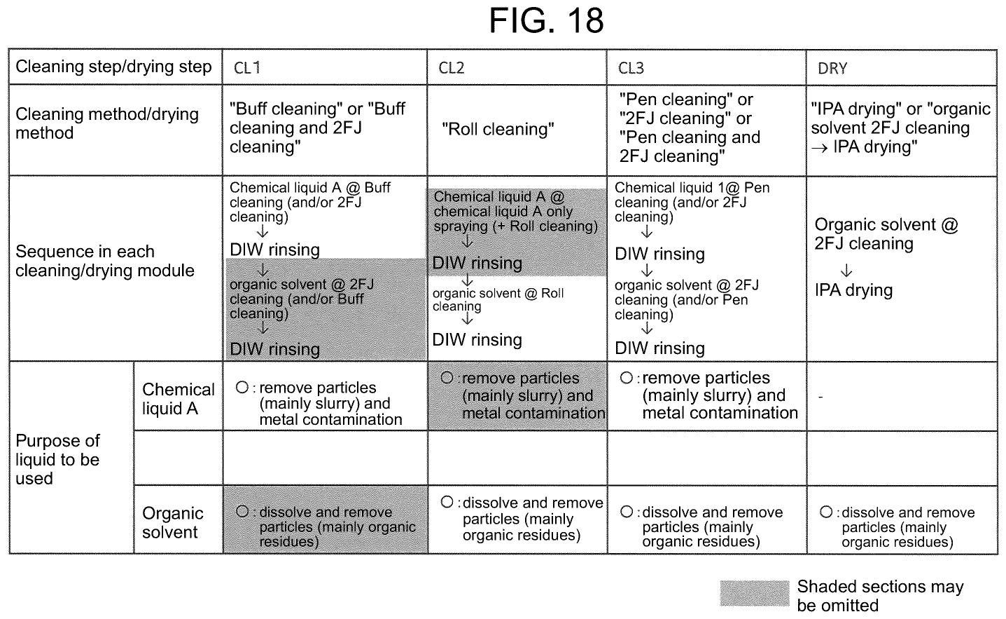

Next, a specific example of the cleaning sequence in the cleaning section 13 of the substrate processing apparatus 10 will be described with reference to FIGS. 15 to 18.

(An Example of a Cleaning Sequence for a Wafer that has W or Ox in a Part of a Surface)

FIG. 15 is a table showing an example of a cleaning sequence for a wafer W that has undergone a tungsten CMP process (a process in which tungsten is removed by polishing except for wiring part) or a silicon oxide CMP process.

In the example shown in FIG. 15, first, with reference to FIG. 1, a polished wafer W that has undergone a tungsten CMP process or a silicon oxide CMP process is transferred from the wafer station 33 to the first cleaning module 311 by the cleaning section transfer mechanism 32.

In the first cleaning module 311, with reference to FIGS. 2, 4A and 4B, the surface of the wafer W is subjected to contact cleaning using a chemical liquid with the first roll cleaning member 41a by: rotating the wafer W supported by the rotation support section 40, and moving the first roll cleaning member 41a to the position over the radius of the wafer W; supplying the chemical liquid to the surface of the wafer W from the first chemical liquid nozzle 42a1 and the second chemical liquid nozzle 42b2; and pressing the first roll cleaning member 41a against the surface of the wafer W with the surface of the wafer W being wetted with the chemical liquid, while the first roll cleaning member 41a is rotated about central axis.

The surface of the wafer W may be further subjected to non-contact cleaning using a chemical liquid by: supplying a chemical liquid to the surface of the wafer W from the non-contact cleaning chemical liquid supply section 44a after, before, or during the contact cleaning of the surface of the wafer W using the chemical liquid with the first roll cleaning member 41a; and swinging the megasonic nozzle 43 in a direction parallel to the surface of the wafer W wetted with the chemical liquid, with the swing arm 43a, while spraying the liquid excited by the ultrasonic vibrator from the megasonic nozzle 43 toward the center of the wafer W.

Cleaning the surface of the wafer W using a chemical liquid removes particles (mainly slurry) from the surface of the wafer W.

After the cleaning of the surface of the wafer W with the chemical liquid is completed, the chemical liquid is washed away from the surface of the wafer W by: setting the first roll cleaning member 41a apart from the surface of the wafer W; and supplying a rinsing liquid from the first to third rinsing liquid nozzles 42a1 to 42a3 to the surface of the wafer W.

Next, the surface of the wafer W is subjected to contact cleaning using an organic solvent with the second roll cleaning member 41b by: keeping the wafer W supported and rotated by the rotation support section 40; moving the second roll cleaning member 41b to a position over the radius of the wafer W; supplying an organic solvent to the surface of the wafer W from the first organic solvent nozzle 42a1 and the second organic solvent nozzle 42b2; and pressing the second roll cleaning member 41b against the surface of the wafer W with the surface of the wafer W being wetted with the organic solvent, while the second roll cleaning member 41b is rotated about the central axis.

Cleaning the surface of the wafer W using an organic solvent dissolves particles (mainly organic residues) depositing on the surface of the wafer W in the organic solvent, and removes the particles.

After the cleaning of the surface of the wafer W with the organic solvent is completed, the organic solvent is washed away from the surface of the wafer W by: setting the second roll cleaning member 41b apart from the surface of the wafer W; and supplying a rinsing liquid from the first to third rinsing liquid nozzles 42a1 to 42a3 to the surface of the wafer W.

With reference to FIG. 1, after the cleaning processing in the first cleaning module 311 is completed, the wafer W is transferred from the first cleaning module 311 to the second cleaning module 312 by the cleaning section transfer mechanism 32.

In the second cleaning module 311, with reference to FIG. 7, the deposits of non-organic matter on the surface of the wafer W are dissolved in a chemical liquid and removed by: keeping the roll cleaning member 61 placed outside the wafer W, rotating the wafer W supported by the rotation support section 60, and supplying a chemical liquid to the surface of the wafer W from the chemical liquid supply section 62b; and wetting the surface of the wafer W with the chemical liquid.

At this time, the surface of the wafer W may be further subjected to contact cleaning using a chemical liquid with the first roll cleaning member 41a by: moving the first roll cleaning member 41a (see FIG. 4A) of the roll cleaning member 61 to a position over the radius of the wafer W; and pressing the first roll cleaning member 41a against the surface of the wafer W while the first roll cleaning member 41a is rotated about the central axis.

Cleaning the surface of the wafer W using a chemical liquid removes metal contamination from the surface of the wafer W.

After the cleaning of the surface of the wafer W with the chemical liquid is completed, the chemical liquid is washed away from the surface of the wafer W by supplying a rinsing liquid from the rinsing liquid supply section 62a to the surface of the wafer W.

With reference to FIG. 1, after the cleaning processing in the second cleaning module 312 is completed, the wafer W is transferred from the second cleaning module 312 to the third cleaning module 313 by the cleaning section transfer mechanism 32.

In the third cleaning module 313, with reference to FIGS. 8 and 9B, the surface of the wafer W is subjected to contact cleaning using a chemical liquid with the first pen cleaning members 71a by: rotating the wafer W supported by the rotation support section 40, and supplying a chemical liquid to the surface of the wafer W from the chemical liquid supply section 74b; pressing the first pen cleaning members 71a against the surface of the wafer W with the surface of the wafer W being wetted with the chemical liquid, while the pen cleaning member 71 is rotated about the central axis; and swinging the pen cleaning member 71 and the two-fluid jet nozzle 72 in a direction parallel to the surface of the wafer W with the swing arm 73.

The surface of the wafer W may be further subjected to non-contact cleaning using a chemical liquid by spraying a jet stream containing a mixture of liquid and carrier gas from the two-fluid jet nozzle 72 toward the center of the wafer W after, before, or during the contact cleaning of the surface of the wafer W using the chemical liquid with the first pen cleaning members 71a.

Instead of the surface of the wafer W being subjected to contact cleaning by the first pen cleaning members 71a using a chemical liquid, the surface of the wafer W may be subjected to non-contact cleaning using a chemical liquid by: keeping the pen cleaning member 71 spaced apart from the surface of the wafer W, rotating the wafer W supported by the rotation support section 40, and supplying a chemical liquid to the surface of the wafer W from the chemical liquid supply section 52b; spraying a jet stream containing a mixture of liquid and carrier gas from the two-fluid jet nozzle 72 toward the center of the wafer W with the surface of the wafer W being wetted with the chemical liquid; and swinging the pen cleaning member 71 and the two-fluid jet nozzle 72 in a direction parallel to the surface of the wafer W with the swing arm 73.

Cleaning the surface of the wafer W using a chemical liquid generates a chemical oxide film on the surface of the wafer W.

After the cleaning of the surface of the wafer W with the chemical liquid is completed, the chemical liquid is washed away from the surface of the wafer W by: setting the first pen cleaning members 71a apart from the surface of the wafer W when the first pen cleaning members 71a have been used for chemical liquid cleaning; and supplying a rinsing liquid from the rinsing liquid supply section 74a to the surface of the wafer W.

Next, as shown in FIG. 8, the surface of the wafer W is subjected to non-contact cleaning using an organic solvent by: keeping the wafer W supported and rotated by the rotation support section; supplying an organic solvent to the surface of the wafer W from the organic solvent supply section 74c; spraying a jet stream containing a mixture of liquid and carrier gas from the two-fluid jet nozzle 72 toward the center of the wafer W with the surface of the wafer W being wetted with the organic solvent; and swinging the pen cleaning member 71 and the two-fluid jet nozzle 72 in a direction parallel to the surface of the wafer W with the swing arm 73.

With reference to FIG. 9C, the surface of the wafer W may be further subjected to contact cleaning using an organic solvent by: pressing the second pen cleaning members 71b against the surface of the wafer W while the pen cleaning member 71 is rotated about the central axis after, before, or during the non-contact cleaning of the surface of the wafer W using the organic solvent with the two-fluid jet nozzle 72.

Instead of the surface of the wafer W being subjected to non-contact cleaning using an organic solvent with the two-fluid jet nozzle 72, the surface of the wafer W is subjected to contact cleaning using an organic solvent with the second pen cleaning members 71b by: keeping the wafer W supported and rotated by the rotation support section 40; and pressing the second pen cleaning members 71b against the surface of the wafer W while the pen cleaning member 71 is rotated about the central axis without spraying a jet stream from the two-fluid jet nozzle 72.

Cleaning the surface of the wafer W using an organic solvent dissolves particles (mainly organic residues) depositing on the surface of the wafer W in the organic solvent, and removes the particles.

After the cleaning of the surface of the wafer W with the organic solvent is completed, the organic solvent is washed away from the surface of the wafer W by: setting the second pen cleaning members 71b apart from the surface of the wafer W when the second pen cleaning members 71b have been used for organic solvent cleaning; and supplying a rinsing liquid from the rinsing liquid supply section 74c to the surface of the wafer W.

With reference to FIG. 1, after the cleaning processing in the third cleaning module 313 is completed, the wafer W is transferred from the third cleaning module 313 to the fourth cleaning module 314 by the cleaning section transfer mechanism 32.

In the fourth cleaning module 314, with reference to FIG. 12, the surface of the wafer W is subjected to non-contact cleaning using an organic solvent by: rotating the wafer W supported by the rotation support section 80, and supplying an organic solvent to the surface of the wafer W from the organic solvent supply section 83; spraying a jet stream containing a mixture of liquid and carrier gas from the two-fluid jet nozzle 82 toward the center of the wafer W with the surface of the wafer W being wetted with the organic solvent; and swinging the two-fluid jet nozzle 82 in a direction parallel to the surface of the wafer W with the swing arm 82a.

Cleaning the surface of the wafer W using an organic solvent dissolves particles (mainly organic residues) depositing on the surface of the wafer W in the organic solvent, and removes the particles.

After the cleaning of the surface of the wafer W with the organic solvent is completed, the two-fluid jet nozzle 82 is moved to the outside of the wafer W. Then, the surface of the wafer W is dried with vapor of an organic solvent (IPA vapor drying) by: keeping the wafer W supported and rotated by the rotation support section 80; first supplying a liquid such as CO₂ water or ultrapure water onto the substrate from the liquid supply nozzle 81a; then spraying vapor of an organic solvent from the drying nozzle 81c toward the surface of the wafer W; and swinging the drying nozzle 81 in a direction parallel to the surface of the wafer W with the swing arm 81a. The drying assist nozzle 81b is used for supplying N₂ or the like to assist or accelerate drying of the wafer W.

Thereafter, with reference to FIG. 1, the cleaned and dried wafer W is taken out by the transfer robot 111 of the loading/unloading section 11 and returned to the wafer cassette 113.

(Another Example of a Cleaning Sequence for a Wafer that has W or Ox on a Part of Surface)

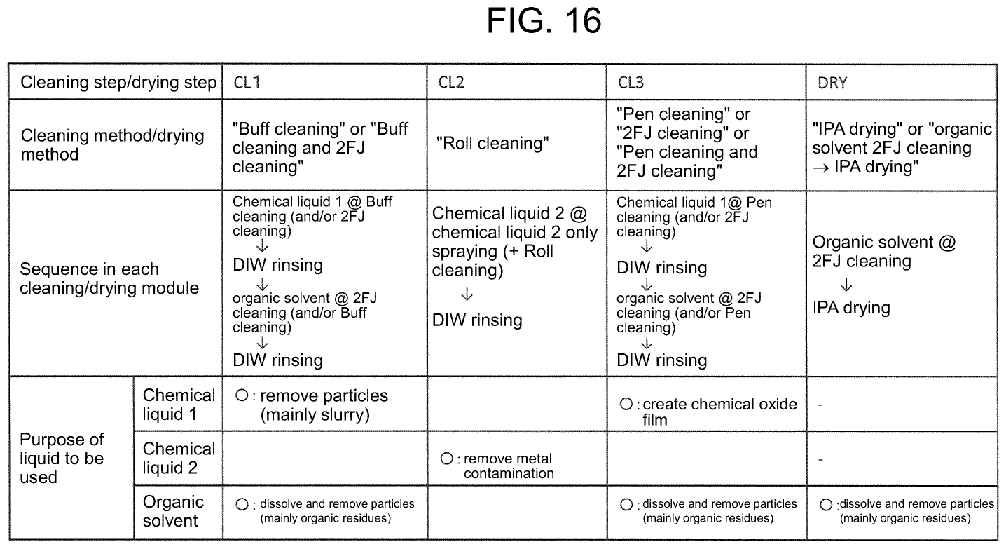

FIG. 16 is a table showing another example of the cleaning sequence for a wafer W that has undergone a tungsten CMP process or a silicon oxide CMP process.

In the example shown in FIG. 16, with reference to FIG. 1, a polished wafer W that has undergone a tungsten CMP process or a silicon oxide CMP process is first transferred from the wafer station 33 to the first cleaning module 311 by the cleaning section transfer mechanism 32.

In the first cleaning module 311, with reference to FIG. 6, the surface of the wafer W is subjected to contact cleaning using a chemical liquid with the buff cleaning member 51 by: rotating the wafer W supported by the rotation support section, and supplying a chemical liquid to the surface of the wafer W from the chemical liquid supply section 52b; pressing the buff cleaning member 51 against the surface of the wafer W with the surface of the wafer W being wetted with the chemical liquid, while the buff cleaning member 51 is rotated about the central axis; and swinging the buff cleaning member 51 in a direction parallel to the surface of the wafer W with the swing arm 51a. In this case, the buff cleaning member 51 is made of, for example, PVA.

The surface of the wafer W may be further subjected to non-contact cleaning using a chemical liquid by: spraying a jet stream containing a mixture of liquid and carrier gas from the two-fluid jet nozzle 53 toward the center of the wafer W after, before, or during the contact cleaning of the surface of the wafer W using the chemical liquid with the buff cleaning member 51; and swinging the two-fluid jet nozzle 53 in a direction parallel to the surface of the wafer W with the swing arm 53a.

Instead of the surface of the wafer W being subjected to contact cleaning using a chemical liquid with the buff cleaning member 51, the surface of the wafer W may be subjected to non-contact cleaning using a chemical liquid by: keeping the buff cleaning member 51 placed outside the wafer W, rotating the wafer W supported by the rotation support section 40, and supplying a chemical liquid to the surface of the wafer W from the chemical liquid supply section 52b; spraying a jet stream containing a mixture of liquid and carrier gas from the two-fluid jet nozzle 53 toward the center of the wafer W with the surface of the wafer W being wetted with the chemical liquid; and swinging the two-fluid jet nozzle 53 in a direction parallel to the surface of the wafer W with the swing arm 53a.

Cleaning the surface of the wafer W using a chemical liquid removes particles (mainly slurry) from the surface of the wafer W.

After the cleaning of the surface of the wafer W with the chemical liquid is completed, the chemical liquid is washed away from the surface of the wafer W by: setting the buff cleaning member 51 apart from the surface of the wafer W when the buff cleaning member 51 has been used for chemical liquid cleaning; and supplying a rinsing liquid from the rinsing liquid supply section 52a to the surface of the wafer W.

Next, as shown in FIG. 6, the surface of the wafer W is subjected to non-contact cleaning using an organic solvent by: keeping the wafer W supported and rotated by the rotation support section; moving the buff cleaning member 51 to the outside of the wafer W; supplying an organic solvent to the surface of the wafer W from the organic solvent supply section 52c; spraying a jet stream containing a mixture of liquid and carrier gas from the two-fluid jet nozzle 53 toward the center of the wafer W with the surface of the wafer W being wetted with the organic solvent; and swinging the two-fluid jet nozzle 53 in a direction parallel to the surface of the wafer W with the swing arm 53a.

The surface of the wafer W may be further subjected to contact cleaning using an organic solvent with the buff cleaning member 51 by: pressing the buff cleaning member 51 against the surface of the wafer W while the buff cleaning member 51 is rotated about the central axis after, before, or during the non-contact cleaning of the surface of the wafer W using the organic solvent with the two-fluid jet nozzle 53; and swinging the buff cleaning member 51 in a direction parallel to the surface of the wafer W with the swing arm 51a. In this case, the buff cleaning member 51 is made of, for example, PTFE. When both buff cleaning using a chemical liquid and buff cleaning using an organic solvent are performed in the first cleaning module 311, a buff cleaning head (support tool) can be used that can selectively bring different buff cleaning members into contact with the wafer W as shown in FIGS. 9A to 9C.

Instead of the surface of the wafer W being subjected to non-contact cleaning using an organic solvent with the two-fluid jet nozzle 53, as shown in FIG. 6, the surface of the wafer W may be subjected to contact cleaning using an organic solvent with the buff cleaning member 51 by: keeping the wafer W supported and rotated by the rotation support section; moving the two-fluid jet nozzle 53 to the outside of the wafer W; supplying an organic solvent to the surface of the wafer W from the organic solvent supply section 52c; pressing the buff cleaning member 51 against the surface of the wafer W with the surface of the wafer W being wetted with the organic solvent, while the buff cleaning member 51 is rotated about the central axis; and swinging the buff cleaning member 51 in a direction parallel to the surface of the wafer W with the swing arm 51a.

Cleaning the surface of the wafer W using an organic solvent dissolves particles (mainly organic residues) depositing on the surface of the wafer W in the organic solvent, and removes the particles.

After the cleaning of the surface of the wafer W with the organic solvent is completed, the organic solvent is washed away from the surface of the wafer W by: setting the buff cleaning member 51 apart from the surface of the wafer W when the buff cleaning member 51 has been used for organic solvent cleaning; and supplying a rinsing liquid from the rinsing liquid supply section 52a to the surface of the wafer W.

With reference to FIG. 1, after the cleaning processing in the first cleaning module 311 is completed, the wafer W is sequentially transferred by the cleaning section transfer mechanism 32 to a second cleaning module 312, a third cleaning module 313, and a fourth cleaning module 314, to be cleaned and dried. In the example shown in FIG. 16, the cleaning and drying processing in the second cleaning module 312, third cleaning module 313, and fourth cleaning module 314 are the same as those in the example shown in FIG. 15, and detailed description thereof will be omitted. With reference to FIG. 1, the cleaned and dried wafer W is taken out by the transfer robot 111 of the loading/unloading section 11 and returned to the wafer cassette 113.

(An Example of a Cleaning Sequence for a Wafer that has Cu on a Part of a Surface)

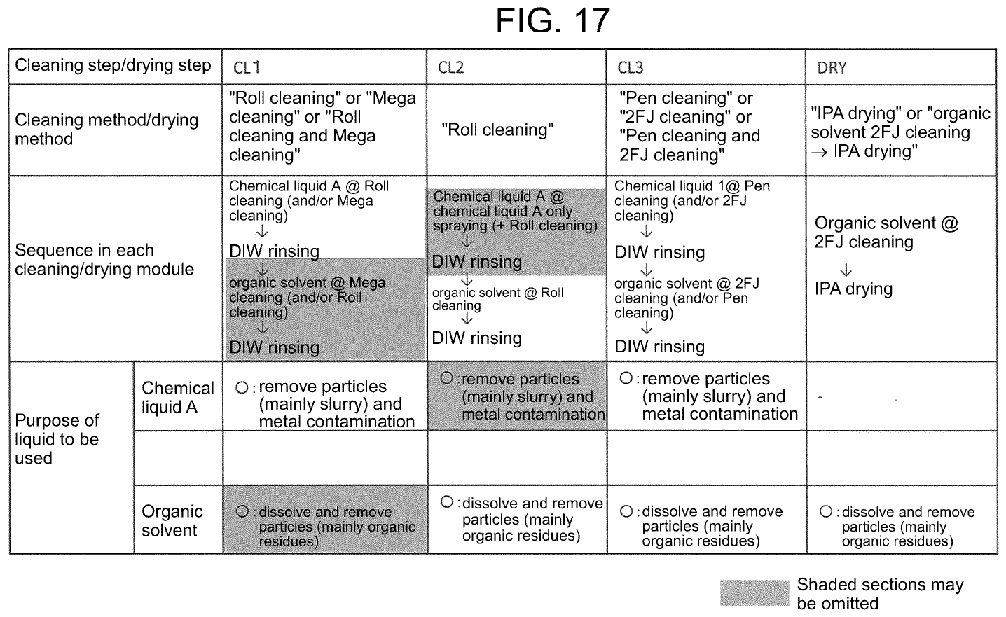

FIG. 17 is a table showing an example of a cleaning sequence for a wafer W that has undergone a copper CMP process (a process in which copper is removed by polishing except for wiring part).

In the example shown in FIG. 17, with reference to FIG. 1, a polished wafer W that has undergone a copper CMP process is first transferred from the wafer station 33 to the first cleaning module 311 by the cleaning section transfer mechanism 32.

In the first cleaning module 311, with reference to FIGS. 2, 4A and 4B, the surface of the wafer W is subjected to contact cleaning using a chemical liquid with the first roll cleaning member 41a by: rotating the wafer W supported by the rotation support section 40, and moving the first roll cleaning member 41a to a position over the radius of the wafer W; supplying the chemical liquid to the surface of the wafer W from the first chemical liquid nozzle 42a1 and the second chemical liquid nozzle 42b2; and pressing the first roll cleaning member 41a against the surface of the wafer W with the surface of the wafer W being wetted with the chemical liquid, while the first roll cleaning member 41a is rotated about the central axis.

The surface of the wafer W may be further subjected to non-contact cleaning using a chemical liquid by: supplying a chemical liquid to the surface of the wafer W from the non-contact cleaning chemical liquid supply section 44a after, before, or during the contact cleaning of the surface of the wafer W using the chemical liquid with the first roll cleaning member 41a; and swinging the megasonic nozzle 43 in a direction parallel to the surface of the wafer W wetted with the chemical liquid, with the swing arm 43a, while spraying the liquid excited by the ultrasonic vibrator from the megasonic nozzle 43 toward the center of the wafer W.

Instead of the surface of the wafer W being subjected to contact cleaning by the first roll cleaning member 41a using a chemical liquid, the surface of the wafer W may be subjected to non-contact cleaning using a chemical liquid by: as shown in FIG. 3, keeping the roll cleaning member 41 placed outside the wafer W, rotating the wafer W supported by the rotation support section 40, and supplying a chemical liquid to the surface of the wafer W from the non-contact cleaning chemical liquid supply section 44a; and swinging the megasonic nozzle 43 in a direction parallel to the surface of the wafer W wetted with the chemical liquid, with the swing arm 43a, while spraying the liquid excited by the ultrasonic vibrator from the megasonic nozzle 43 toward the center of the wafer W.

Cleaning the surface of the wafer W using a chemical liquid removes particles (mainly slurry) and metal contamination from the surface of the wafer W.

After the cleaning of the surface of the wafer W with the chemical liquid is completed, the chemical liquid is washed away from the surface of the wafer W by: setting the first roll cleaning member 41a apart from the surface of the wafer W when the first roll cleaning member 41a has been used for chemical liquid cleaning; and supplying a rinsing liquid from the first to third rinsing liquid nozzles 42a1 to 42a3 to the surface of the wafer W.

Next, the surface of the wafer W is subjected to non-contact cleaning using an organic solvent by: keeping the wafer W supported and rotated by the rotation support section 40; supplying an organic solvent to the surface of the wafer W from the non-contact cleaning organic solvent supply section 44b; and swinging the megasonic nozzle 43 in a direction parallel to the surface of the wafer W wetted with the organic solvent, with the swing arm 43a, while spraying the liquid excited by the ultrasonic vibrator from the megasonic nozzle 43 toward the center of the wafer W.

The surface of the wafer W may be subjected to contact cleaning using an organic solvent with the second roll cleaning member 41b by: as shown in FIGS. 5A and 5B, moving the second roll cleaning member 41b to a position over the radius of the wafer W after, before, or during the non-contact cleaning of the surface of the wafer W using the organic solvent with the megasonic nozzle 43; supplying an organic solvent to the surface of the wafer W from the first organic solvent nozzle 42a1 and the second organic solvent nozzle 42b2; and pressing the second roll cleaning member 41b against the surface of the wafer W with the surface of the wafer W being wetted with the organic solvent, while the second roll cleaning member 41b is rotated about the central axis.

Instead of non-contact cleaning of the surface of the wafer W using an organic solvent by the megasonic nozzle 43, the surface of the wafer W may be subjected to contact cleaning using an organic solvent with the second roll cleaning member 41b by: with reference to FIGS. 2, 5A and 5B, keeping the wafer W supported and rotated by the rotation support section 40; moving the second roll cleaning member 41b to a position over the radius of the wafer W; supplying an organic solvent to the surface of the wafer W from the first organic solvent nozzle 42c1 and the second organic solvent nozzle 42c2; and pressing the second roll cleaning member 41b against the surface of the wafer W with the surface of the wafer W being wetted with the organic solvent, while the second roll cleaning member 41b is rotated about the central axis.

Cleaning the surface of the wafer W using an organic solvent dissolves particles (mainly organic residues) depositing on the surface of the wafer W in the organic solvent, and removes the particles.

After the cleaning of the surface of the wafer W with the organic solvent is completed, the organic solvent is washed away from the surface of the wafer W by: setting the second roll cleaning member 41b apart from the surface of the wafer W when the second roll cleaning member 41b has been used for organic solvent cleaning; and supplying a rinsing liquid from the first to third rinsing liquid nozzles 42a1 to 42a3 to the surface of the wafer W.

Note that, in the first cleaning module 311, the cleaning processing using an organic solvent and the subsequent rinsing process are not necessarily essential and may be omitted.

With reference to FIG. 1, after the cleaning processing in the first cleaning module 311 is completed, the wafer W is transferred from the first cleaning module 311 to the second cleaning module 312 by the cleaning section transfer mechanism 32.

In the second cleaning module 311, with reference to FIG. 7, the deposits of non-organic matter on the surface of the wafer W are dissolved in a chemical liquid and removed by: keeping the roll cleaning member 61 placed outside the wafer W, rotating the wafer W supported by the rotation support section 60, and supplying a chemical liquid to the surface of the wafer W from the chemical liquid supply section 62b; and wetting the surface of the wafer W with the chemical liquid.

At this time, the surface of the wafer W may be further subjected to contact cleaning using a chemical liquid with the first roll cleaning member 41a by: moving the first roll cleaning member 41a (see FIG. 4A) of the roll cleaning member 61 to a position over the radius of the wafer W; and pressing the first roll cleaning member 41a against the surface of the wafer W while the first roll cleaning member 41a is rotated about the central axis.

Cleaning the surface of the wafer W using a chemical liquid removes particles (mainly slurry) and metal contamination from the surface of the wafer W.

After the cleaning of the surface of the wafer W with the chemical liquid is completed, the chemical liquid is washed away from the surface of the wafer W by supplying the rinsing liquid from the rinsing liquid supply section 62a to the surface of the wafer W.

Next, the surface of the wafer W is subjected to contact cleaning using an organic solvent with the second roll cleaning member 41b by: keeping the wafer W supported and rotated by the rotation support section 60; supplying an organic solvent to the surface of the wafer W from the organic solvent supply section 62c; moving the second roll cleaning member 41b (see FIG. 5A) of the roll cleaning member 61 to a position over the radius of the wafer W with the surface of the wafer W being wetted with the organic solvent; and pressing the second roll cleaning member 41b against the surface of the wafer W while the second roll cleaning member 41b is rotated about the central axis.

Cleaning the surface of the wafer W using an organic solvent dissolves particles (mainly organic residues) depositing on the surface of the wafer W in the organic solvent, and removes the particles.

After the cleaning of the surface of the wafer W with the organic solvent is completed, the organic solvent is washed away from the surface of the wafer W by: setting the roll cleaning member 61 apart from the surface of the wafer W; and supplying a rinsing liquid from the rinsing liquid supply section 62a to the surface of the wafer W.

Note that, in the second cleaning module 312, the cleaning processing using a chemical liquid and the subsequent rinsing process are not necessarily essential and may be omitted.

With reference to FIG. 1, after the cleaning processing in the second cleaning module 312 is completed, the wafer W is transferred from the second cleaning module 312 to the third cleaning module 313 by the cleaning section transfer mechanism 32.

In the third cleaning module 313, with reference to FIGS. 8 and 9B, the surface of the wafer W is subjected to contact cleaning using a chemical liquid with the first pen cleaning members 71a by: rotating the wafer W supported by the rotation support section 40, and supplying a chemical liquid to the surface of the wafer W from the chemical liquid supply section 74b; pressing the first pen cleaning members 71a against the surface of the wafer W with the surface of the wafer W being wetted with the chemical liquid, while the pen cleaning member 71 is rotated about the central axis; and swinging the pen cleaning member 71 and the two-fluid jet nozzle 72 in a direction parallel to the surface of the wafer W with the swing arm 73.

The surface of the wafer W may be further subjected to non-contact cleaning using a chemical liquid by spraying a jet stream containing a mixture of liquid and carrier gas from the two-fluid jet nozzle 72 toward the center of the wafer W after, before, or during the contact cleaning of the surface of the wafer W using the chemical liquid with the first pen cleaning members 71a.

Instead of the surface of the wafer W being subjected to contact cleaning by the first pen cleaning members 71a using a chemical liquid, the surface of the wafer W may be subjected to non-contact cleaning using a chemical liquid by: keeping the pen cleaning member 71 spaced apart from the surface of the wafer W, rotating the wafer W supported by the rotation support section 40, and supplying a chemical liquid to the surface of the wafer W from the chemical liquid supply section 52b; spraying a jet stream containing a mixture of liquid and carrier gas from the two-fluid jet nozzle 72 toward the center of the wafer W with the surface of the wafer W being wetted with the chemical liquid; and swinging the pen cleaning member 71 and the two-fluid jet nozzle 72 in a direction parallel to the surface of the wafer W with the swing arm 73.

Cleaning the surface of the wafer W using a chemical liquid removes particles (mainly slurry) and metal contamination from the surface of the wafer W.

After the cleaning of the surface of the wafer W with the chemical liquid is completed, the chemical liquid is washed away from the surface of the wafer W by: setting the first pen cleaning members 71a apart from the surface of the wafer W when the first pen cleaning members 71a have been used for chemical liquid cleaning; and supplying a rinsing liquid from the rinsing liquid supply section 74a to the surface of the wafer W.

Next, as shown in FIG. 8, the surface of the wafer W is subjected to non-contact cleaning using an organic solvent by: keeping the wafer W supported and rotated by the rotation support section; supplying an organic solvent to the surface of the wafer W from the organic solvent supply section 74c; spraying a jet stream containing a mixture of liquid and carrier gas from the two-fluid jet nozzle 72 toward the center of the wafer W with the surface of the wafer W being wetted with the organic solvent; and swinging the pen cleaning member 71 and the two-fluid jet nozzle 72 in a direction parallel to the surface of the wafer W with the swing arm 73.

With reference to FIG. 9C, the surface of the wafer W may be further subjected to contact cleaning using an organic solvent by: pressing the second pen cleaning members 71b against the surface of the wafer W while the pen cleaning member 71 is rotated about the central axis after, before, or during the non-contact cleaning of the surface of the wafer W using the organic solvent with the two-fluid jet nozzle 72.

Instead of the surface of the wafer W being subjected to non-contact cleaning using an organic solvent with the two-fluid jet nozzle 72, the surface of the wafer W is subjected to contact cleaning using an organic solvent with the second pen cleaning members 71b by: keeping the wafer W supported and rotated by the rotation support section 40; and pressing the second pen cleaning members 71b against the surface of the wafer W while the pen cleaning member 71 is rotated about the central axis without spraying a jet stream from the two-fluid jet nozzle 72.

Cleaning the surface of the wafer W using an organic solvent dissolves particles (mainly organic residues) depositing on the surface of the wafer W in the organic solvent, and removes the particles.

After the cleaning of the surface of the wafer W with the organic solvent is completed, the organic solvent is washed away from the surface of the wafer W by: setting the second pen cleaning members 71b apart from the surface of the wafer W when the second pen cleaning members 71b have been used for organic solvent cleaning; and supplying a rinsing liquid from the rinsing liquid supply section 74c to the surface of the wafer W.

With reference to FIG. 1, after the cleaning processing in the third cleaning module 313 is completed, the wafer W is transferred from the third cleaning module 313 to the fourth cleaning module 314 by the cleaning section transfer mechanism 32.

In the fourth cleaning module 314, with reference to FIG. 12, the surface of the wafer W is subjected to non-contact cleaning using an organic solvent by: rotating the wafer W supported by the rotation support section 80, and supplying an organic solvent to the surface of the wafer W from the organic solvent supply section 83; spraying a jet stream containing a mixture of liquid and carrier gas from the two-fluid jet nozzle 82 toward the center of the wafer W with the surface of the wafer W being wetted with the organic solvent; and swinging the two-fluid jet nozzle 82 in a direction parallel to the surface of the wafer W with the swing arm 82a.

Cleaning the surface of the wafer W using an organic solvent dissolves particles (mainly organic residues) depositing on the surface of the wafer W in the organic solvent, and removes the particles.

After the cleaning of the surface of the wafer W with the organic solvent is completed, the two-fluid jet nozzle 82 is moved to the outside of the wafer W. Then, the surface of the wafer W is dried with vapor of an organic solvent (IPA vapor drying) by: keeping the wafer W supported and rotated by the rotation support section 80; first supplying a liquid such as CO₂ water or ultrapure water onto the substrate from the liquid supply nozzle 81a; then spraying vapor of an organic solvent from the drying nozzle 81c toward the surface of the wafer W; and swinging the drying nozzle 81 in a direction parallel to the surface of the wafer W with the swing arm 81a. The drying assist nozzle 81b is used for supplying N₂ or the like to assist or accelerate drying of the wafer W.

Thereafter, with reference to FIG. 1, the cleaned and dried wafer W is taken out by the transfer robot 111 of the loading/unloading section 11 and returned to the wafer cassette 113.

(Another Example of a Cleaning Sequence for a Wafer that has Cu on a Part of a Surface)

FIG. 16 is a table showing another example of the cleaning sequence for a wafer W that has undergone a copper CMP process.

In the example shown in FIG. 16, with reference to FIG. 1, a polished wafer W that has undergone a copper CMP process is first transferred from the wafer station 33 to the first cleaning module 311 by the cleaning section transfer mechanism 32.

In the first cleaning module 311, with reference to FIG. 6, the surface of the wafer W is subjected to contact cleaning using a chemical liquid with the buff cleaning member 51 by: rotating the wafer W supported by the rotation support section, and supplying a chemical liquid to the surface of the wafer W from the chemical liquid supply section 52b; pressing the buff cleaning member 51 against the surface of the wafer W with the surface of the wafer W being wetted with the chemical liquid, while the buff cleaning member 51 is rotated about the central axis; and swinging the buff cleaning member 51 in a direction parallel to the surface of the wafer W with the swing arm 51a. In this case, the buff cleaning member 51 is made of, for example, PVA.

The surface of the wafer W may be further subjected to non-contact cleaning using a chemical liquid by: spraying a jet stream containing a mixture of liquid and carrier gas from the two-fluid jet nozzle 53 toward the center of the wafer W after, before, or during the contact cleaning of the surface of the wafer W using the chemical liquid with the buff cleaning member 51; and swinging the two-fluid jet nozzle 53 in a direction parallel to the surface of the wafer W with the swing arm 53a.

Instead of the surface of the wafer W being subjected to contact cleaning using a chemical liquid with the buff cleaning member 51, the surface of the wafer W may be subjected to non-contact cleaning using a chemical liquid by: keeping the buff cleaning member 51 placed outside the wafer W, rotating the wafer W supported by the rotation support section 40, and supplying a chemical liquid to the surface of the wafer W from the chemical liquid supply section 52b; spraying a jet stream containing a mixture of liquid and carrier gas from the two-fluid jet nozzle 53 toward the center of the wafer W with the surface of the wafer W being wetted with the chemical liquid; and swinging the two-fluid jet nozzle 53 in a direction parallel to the surface of the wafer W with the swing arm 53a.

Cleaning the surface of the wafer W using a chemical liquid removes particles (mainly slurry) and metal contamination from the surface of the wafer W.

After the cleaning of the surface of the wafer W with the chemical liquid is completed, the chemical liquid is washed away from the surface of the wafer W by: setting the buff cleaning member 51 apart from the surface of the wafer W when the buff cleaning member 51 has been used for chemical liquid cleaning; and supplying a rinsing liquid from the rinsing liquid supply section 52a to the surface of the wafer W.

Next, as shown in FIG. 6, the surface of the wafer W is subjected to non-contact cleaning using an organic solvent by: keeping the wafer W supported and rotated by the rotation support section; moving the buff cleaning member 51 to the outside of the wafer W; supplying an organic solvent to the surface of the wafer W from the organic solvent supply section 52c; spraying a jet stream containing a mixture of liquid and carrier gas from the two-fluid jet nozzle 53 toward the center of the wafer W with the surface of the wafer W being wetted with the organic solvent; and swinging the two-fluid jet nozzle 53 in a direction parallel to the surface of the wafer W with the swing arm 53a.

The surface of the wafer W may be further subjected to contact cleaning using an organic solvent with the buff cleaning member 51 by: pressing the buff cleaning member 51 against the surface of the wafer W while the buff cleaning member 51 is rotated about the central axis after, before, or during the non-contact cleaning of the surface of the wafer W using the organic solvent with the two-fluid jet nozzle 53; and swinging the buff cleaning member 51 in a direction parallel to the surface of the wafer W with the swing arm 51a. In this case, the buff cleaning member 51 is made of, for example, PTFE. When both buff cleaning using a chemical liquid and buff cleaning using an organic solvent are performed in the first cleaning module 311, a buff cleaning head (support tool) can be used that can selectively bring different buff cleaning members into contact with the wafer W as shown in FIGS. 9A to 9C.

Instead of the surface of the wafer W being subjected to non-contact cleaning using an organic solvent with the two-fluid jet nozzle 53, as shown in FIG. 6, the surface of the wafer W may be subjected to contact cleaning using an organic solvent with the buff cleaning member 51 by: keeping the wafer W supported and rotated by the rotation support section; moving the two-fluid jet nozzle 53 to the outside of the wafer W; supplying an organic solvent to the surface of the wafer W from the organic solvent supply section 52c; pressing the buff cleaning member 51 against the surface of the wafer W with the surface of the wafer W being wetted with the organic solvent, while the buff cleaning member 51 is rotated about the central axis; and swinging the buff cleaning member 51 in a direction parallel to the surface of the wafer W with the swing arm 51a.

Cleaning the surface of the wafer W using an organic solvent dissolves particles (mainly organic residues) depositing on the surface of the wafer W in the organic solvent, and removes the particles.

After the cleaning of the surface of the wafer W with the organic solvent is completed, the organic solvent is washed away from the surface of the wafer W by: setting the buff cleaning member 51 apart from the surface of the wafer W when the buff cleaning member 51 has been used for organic solvent cleaning; and supplying a rinsing liquid from the rinsing liquid supply section 52a to the surface of the wafer W.

Note that, in the first cleaning module 311, the cleaning processing using an organic solvent and the subsequent rinsing process are not necessarily essential and may be omitted.

With reference to FIG. 1, after the cleaning processing in the first cleaning module 311 is completed, the wafer W is sequentially transferred by the cleaning section transfer mechanism 32 to a second cleaning module 312, a third cleaning module 313, and a fourth cleaning module 314, to be cleaned and dried. In the example shown in FIG. 16, the cleaning and drying processing in the second cleaning module 312, third cleaning module 313, and fourth cleaning module 314 are the same as those in the example shown in FIG. 15, and detailed description thereof will be omitted. With reference to FIG. 1, the cleaned and dried wafer W is taken out by the transfer robot 111 of the loading/unloading section 11 and returned to the wafer cassette 113.

Note that the cleaning sequence in the cleaning section 13 of the substrate processing apparatus 10 has been described with reference to FIGS. 15 to 18, but not all the first cleaning module 311, the second cleaning module 312, and the third cleaning module 313 need to perform cleaning using a chemical liquid and cleaning using an organic solvent. The cleaning sequence may be such that: any one of the cleaning modules performs cleaning using a chemical liquid and cleaning using an organic solvent; and the other cleaning modules each perform conventional cleaning processing (that is, only cleaning using a chemical liquid). In addition, when the fourth cleaning module 314 performs jet cleaning containing an organic solvent solution or an organic solvent, and drying processing using organic solvent vapor or an organic solvent solution, the first cleaning module 311, the second cleaning module 312, and the third cleaning module 313 may perform conventional cleaning (that is, only cleaning using a chemical liquid).

Although the embodiments and modifications of the present technique have been described above by way of example, the scope of the present technique is not limited to these, and the embodiments and modifications may be changed or modified according to the purpose within the scope of the claims. Moreover, each of the embodiments and modifications can be combined as appropriate within a range that does not conflict with the processing contents.

For example, in the embodiment described above, with reference to FIG. 11, the third cleaning module 313 is provided with a configuration such that a diluted organic solvent is supplied to the front surface of the wafer W and warm pure water is supplied to the front surface or back surface of the wafer W to raise the temperature of the wafer W in advance. However, the present invention is not limited to this, and the first cleaning module 311 and/or the second cleaning module 312 may be provided with the configuration.

What is claimed is:

1. A cleaning apparatus comprising:
a rotation support section that supports and rotates a substrate;
a chemical liquid supply section that supplies a chemical liquid other than an organic solvent to a surface of the substrate;
an organic solvent supply section that supplies an organic solvent to a surface of the substrate; and
cleaning means that cleans a surface of the substrate supported by the rotation support section using a chemical liquid from the chemical liquid supply section, and then cleans a surface of the substrate using an organic solvent from the organic solvent supply section with the substrate being kept supported by the rotation support section.

2. The cleaning apparatus according to claim 1, wherein
the cleaning means includes:
a first contact cleaning member that comes into contact with a surface of the substrate to clean the surface when a chemical liquid is supplied from the chemical liquid supply section; and
a second contact cleaning member different from the first contact cleaning member, the second contact cleaning member coming into contact with a surface of the substrate to clean the surface when an organic solvent is supplied from the organic solvent supply section.

3. The cleaning apparatus according to claim 2, wherein each of the first contact cleaning member and the second contact cleaning member is a pen cleaning member or a buff cleaning member that comes into contact with a surface of the substrate while rotating around a central axis perpendicular to the surface of the substrate to clean the surface.

4. The cleaning apparatus according to claim 3, wherein the first contact cleaning member and the second contact cleaning member are coaxially placed and supported on an identical swing arm in a plan view.

5. The cleaning apparatus according to claim 2, wherein each of the first contact cleaning member and the second contact cleaning member is a roll cleaning member that comes into contact with a surface of the substrate to clean the surface while rotating around a central axis parallel to the surface of the substrate.

6. The cleaning apparatus according to claim 2, wherein a material of the second contact cleaning member is polytetrafluoroethylene (PTFE).

7. The cleaning apparatus according to claim 1, wherein the cleaning means includes a non-contact cleaning nozzle that sprays fluid onto a surface of the substrate to clean the surface when a chemical liquid is supplied from the chemical liquid supply section and when an organic solvent is supplied from the organic solvent supply section.

8. The cleaning apparatus according to claim 7, wherein the non-contact cleaning nozzle is a two-fluid jet nozzle that sprays a jet stream containing a mixture of liquid and carrier gas, or a megasonic nozzle that sprays a liquid excited by an ultrasonic vibrator.

9. The cleaning apparatus according to claim 7, wherein the chemical liquid supply section and/or the organic solvent supply section are provided in the non-contact cleaning nozzle.

10. The cleaning apparatus according to claim 1, wherein
the cleaning means includes:
a contact cleaning member that comes into contact with a surface of the substrate to clean the surface when a chemical liquid is supplied from the chemical liquid supply section; and
a non-contact cleaning nozzle that sprays fluid onto a surface of the substrate to clean the surface when an organic solvent is supplied from the organic solvent supply section.

11. The cleaning apparatus according to claim 10, wherein the non-contact cleaning nozzle sprays fluid onto a surface of the substrate to clean the surface also when a chemical liquid is supplied from the chemical liquid supply section.

12. The cleaning apparatus according to claim 1, wherein
the cleaning means includes:
a non-contact cleaning nozzle that sprays fluid onto a surface of the substrate to clean the surface when a chemical liquid is supplied from the chemical liquid supply section; and
a contact cleaning member that comes into contact with a surface of the substrate to clean the surface when an organic solvent is supplied from the organic solvent supply section.

13. The cleaning apparatus according to claim 12, wherein the non-contact cleaning nozzle sprays fluid onto a surface of the substrate to clean the surface also when an organic solvent is supplied from the organic solvent supply section.

14. The cleaning apparatus according to claim 10, wherein a material of the contact cleaning member is polytetrafluoroethylene (PTFE).

15. The cleaning apparatus according to claim 10, wherein the contact cleaning member is a pen cleaning member or a buff cleaning member that comes into contact with a surface of the substrate to clean the surface while rotating around a central axis perpendicular to the surface of the substrate.

16. The cleaning apparatus according to claim 10, wherein the contact cleaning member is a roll cleaning member that comes into contact with a surface of the substrate to clean the surface while rotating around a central axis parallel to the surface of the substrate.

17. The cleaning apparatus according to claim 10, wherein the non-contact cleaning nozzle is a two-fluid jet nozzle that sprays a jet stream containing a mixture of liquid and carrier gas, or a megasonic nozzle that sprays a liquid excited by an ultrasonic vibrator.

18. A cleaning apparatus comprising:
a rotation support section that supports and rotates a substrate;
an organic solvent supply section that supplies an organic solvent to a surface of the substrate;
a non-contact cleaning nozzle that sprays fluid onto a surface of the substrate supported by the rotation support section to clean the surface when an organic solvent is supplied from the organic solvent supply section; and
a drying nozzle that sprays organic solvent vapor onto a surface of the substrate to dry the surface with the substrate being kept supported by the rotation support section.

19. The cleaning apparatus according to claim 18, wherein the non-contact cleaning nozzle is a two-fluid jet nozzle that sprays a jet stream containing a mixture of liquid and carrier gas, or a megasonic nozzle that sprays a liquid excited by an ultrasonic vibrator.

20. The cleaning apparatus according to claim 18, wherein the organic solvent supply section is provided in the non-contact cleaning nozzle.

21. The cleaning apparatus according to claim 1, further including an organic solvent heating section that is disposed on an upstream side of the organic solvent supply section, and dilutes and heats, with warm water, an organic solvent to be supplied to the organic solvent supply section.

22. The cleaning apparatus according to claim 1, further including a first warm water supply nozzle that supplies warm water to a surface of the substrate to dilute and heat an organic solvent from the organic solvent supply section on the surface of the substrate when the organic solvent is supplied from the organic solvent supply section.

23. The cleaning apparatus according to claim 1, further including a second warm water supply nozzle that supplies warm water to a back surface of the substrate to heat the substrate when an organic solvent is supplied from the organic solvent supply section, and thereby heats the organic solvent from the organic solvent supply section on a front surface of the substrate with heat of the substrate.

24. A substrate processing apparatus, comprising:
a polishing section that polishes a substrate; and
a cleaning section that cleans a polished substrate,
wherein the cleaning section includes a cleaning apparatus according to claim 1.

25. A cleaning method comprising:
a step of supporting and rotating a substrate with a rotation support section;
a step of cleaning a surface of the substrate supported by the rotation support section using a chemical liquid; and
a step of cleaning a surface of the substrate using an organic solvent with the substrate being kept supported by the rotation support section.

26. A cleaning method comprising:
a step of supporting and rotating a substrate with a rotation support section;
a step of cleaning a surface of the substrate supported by the rotation support section using an organic solvent; and
a step of spraying organic solvent vapor onto a surface of the substrate to dry the surface with the substrate being kept supported by the rotation support section.
